(19) United States
(12) Patent Application Publication
(10) Pub. No.: US 2026/0206274 A1
(43) Pub. Date: Jul. 16, 2026

(54) SEMICONDUCTOR DEVICE

(71) Applicant: Semiconductor Energy Laboratory Co., Ltd., Atsugi-shi, Kanagawa-ken (JP)

(72) Inventors: Shoki MIYATA, Atsugi (JP); Takanori MATSUZAKI, Atsugi (JP)

(21) Appl. No.: 19/135,445

(22) PCT Filed: Dec. 15, 2023
(86) PCT No.: PCT/IB2023/062744

§ 371 Date: Jun. 4, 2025

(30) Foreign Application Priority Data
Dec. 22, 2022 (JP) 2022-205647

(51) Int. Cl. H10D 62/86; H10D 64/23; H10D 64/27

(52) U.S. Cl. CPC H10D 62/86; H10D 64/256; H10D 64/512

(57) ABSTRACT

A novel semiconductor device is provided. The semiconductor device includes a transistor and a capacitor element; a first conductive layer; a first insulating layer over the first conductive layer; a second conductive layer over the first insulating layer; an opening passing through the first insulating layer and the second conductive layer and overlapping with the first conductive layer; a semiconductor layer including a region in contact with the first insulating layer, a region in contact with the first conductive layer, and a region in contact with the second conductive layer in the opening; a second insulating layer over the semiconductor layer; a third conductive layer over the second insulating layer; a third insulating layer over the third conductive layer; and a fourth conductive layer over the third insulating layer. The first conductive layer functions as one of a source electrode and a drain electrode of the transistor, and the second conductive layer functions as the other of the source electrode and the drain electrode of the transistor. The fourth conductive layer functions as one electrode of the capacitor element, and the third conductive layer functions as a gate electrode of the transistor and the other electrode of the capacitor element. The third insulating layer has ferroelectricity.

### TECHNICAL FIELD

One embodiment of the present invention relates to a semiconductor device.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

Thus, examples of the technical field of one embodiment of the present invention include a semiconductor device, a display device, a liquid crystal display device, a light-emitting device, a power storage device, an imaging device, a storage device, a signal processing device, a processor, an electronic device, a system, a driving method thereof, a manufacturing method thereof, a testing method thereof, and a usage method thereof.

### BACKGROUND ART

In recent years, semiconductor devices such as LSI, CPUs, and memories (storage devices) have been developed. These semiconductor devices have been used in various electronic devices such as computers and portable information terminals. In addition, memories under development employ various storage systems for intended uses such as temporary storage at the time of executing arithmetic processing and long-term storage of data. Examples of memories with typical storage systems include a DRAM, an SRAM, and a flash memory.

Memories using ferroelectrics have been actively researched and developed as disclosed in Non-Patent Document 1. For the next-generation ferroelectric memories, researches on hafnium oxide, such as research on ferroelectric HfO₂-based materials (Non-Patent Document 2); research on ferroelectricity of a Hf_{0.5}Zr_{0.5}O₂ thin film (Non-Patent Document 3); research on ferroelectricity of a HfO₂ thin film (Non-Patent Document 4); and demonstration of integration of an FeRAM (Ferroelectric Random Access Memory) using a ferroelectric Hf_{0.5}Zr_{0.5}O₂ and a CMOS (Non-Patent Document 5) have been actively carried out.

### REFERENCES

### Non-Patent Documents

[Non-Patent Document 1] T. S. Boescke, et al., “Ferroelectricity in hafnium oxide thin films”, APL99, 2011

[Non-Patent Document 2] Zhen Fan, et al., “Ferroelectric HfO₂-based materials for next-generation ferroelectric memories”, JOURNAL OF ADVANCED DIELECTRICS, Vol. 6, No. 2, 2016

[Non-Patent Document 3] Jun Okuno, et al., “SoC compatible 1T1C FeRAM memory array based on ferroelectric Hf_{0.5}Zr_{0.5}O₂”, VLSI 2020

[Non-Patent Document 4] Akira Toriumi, “Ferroelectric properties of thin HfO₂ films”, the Japan Society of Applied Physics, Vol. 88, No. 9, 2019

[Non-Patent Document 5] T. Francois, et al., “Demonstration of BEOL-compatible ferroelectric Hf_{0.5}Zr_{0.5}O₂ scaled FeRAM co-integrated with 130 nm CMOS for embedded NVM applications”, IEDM 2019

### SUMMARY OF THE INVENTION

### Problems to be Solved by the Invention

An object of one embodiment of the present invention is to provide a novel semiconductor device. Another object of one embodiment of the present invention is to provide a semiconductor device that occupies a small area. Another object of one embodiment of the present invention is to provide a highly reliable semiconductor device. Another object of one embodiment of the present invention is to provide a semiconductor device with low power consumption. Another object of one embodiment of the present invention is to provide a semiconductor device with high storage capacity.

Note that the objects of one embodiment of the present invention are not limited to the objects listed above. The objects listed above do not preclude the existence of other objects. The other objects are objects that are not described in this section and will be described below. The objects that are not described in this section will be derived from the description of the specification, the drawings, and the like and can be extracted as appropriate from the description by those skilled in the art. One embodiment of the present invention does not have to achieve all of the objects listed above and the other objects. One embodiment of the present invention achieves at least one of the objects listed above and the other objects.

### Means for Solving the Problems

One embodiment of the present invention is a semiconductor device including a transistor and a capacitor element; a first conductive layer including a region functioning as one of a source electrode and a drain electrode of the transistor; a first insulating layer including a region positioned over the first conductive layer; a second conductive layer including a region functioning as the other of the source electrode and the drain electrode of the transistor and including a region positioned over the first insulating layer; an opening passing through the first insulating layer and the second conductive layer and overlapping with the first conductive layer; a semiconductor layer including a region in contact with the first insulating layer, a region in contact with the first conductive layer, and a region in contact with the second conductive layer; a third conductive layer including a region functioning as a gate electrode of the transistor; a second insulating layer including a region functioning as a gate insulating layer of the transistor and including a region interposed between the semiconductor layer and the third conductive layer in the opening; a fourth conductive layer including a region functioning as one electrode of the capacitor element; and a third insulating layer including a region functioning as a dielectric layer of the capacitor element and including a region interposed between the third conductive layer and the fourth conductive layer in the opening. The third conductive layer includes a region functioning as the other electrode of the capacitor element, and the third insulating layer has ferroelectricity.

The semiconductor layer preferably includes an oxide semiconductor. The oxide semiconductor preferably includes at least one of indium and zinc. The third insulating layer preferably includes at least one of hafnium and zirconium. The first insulating layer may include a layer including silicon and nitrogen and a layer including silicon and oxygen.

### Effect of the Invention

One embodiment of the present invention can provide a novel semiconductor device. Another embodiment of the present invention can provide a semiconductor device that occupies a small area. Another embodiment of the present invention can provide a highly reliable semiconductor device. Another embodiment of the present invention can provide a semiconductor device with low power consumption. Another embodiment of the present invention can provide a semiconductor device with high storage capacity.

Note that the effects of one embodiment of the present invention are not limited to the effects listed above. The effects listed above do not preclude the existence of other effects. Accordingly, one embodiment of the present invention does not have the effects listed above in some cases. Note that the other effects are effects that are not described in this section and will be described below. The other effects are derived from the description of the specification, the drawings, and the like and can be extracted as appropriate from the description by those skilled in the art. One embodiment of the present invention has at least one of the effects listed above and the other effects.

### BRIEF DESCRIPTION OF THE DRAWINGS

FIG. 1A and FIG. 1B are diagrams illustrating a structure example of a semiconductor device.

FIG. 1C is an equivalent circuit diagram of the semiconductor device.

FIG. 2A and FIG. 2B are diagrams illustrating a structure example of a semiconductor device.

FIG. 3A to FIG. 3E are diagrams illustrating structure examples of a semiconductor device.

FIG. 4A and FIG. 4B are diagrams illustrating structure examples of a semiconductor device.

FIG. 5A to FIG. 5C are diagrams illustrating a structure example of a semiconductor device.

FIG. 6A to FIG. 6C are diagrams illustrating a structure example of a semiconductor device.

FIG. 7A to FIG. 7C are diagrams illustrating a structure example of a semiconductor device.

FIG. 8A and FIG. 8B are diagrams illustrating structure examples of a semiconductor device.

FIG. 9A and FIG. 9B are diagrams illustrating a structure example of a semiconductor device.

FIG. 10A and FIG. 10B are diagrams illustrating structure examples of a semiconductor device.

FIG. 11A to FIG. 11C are diagrams illustrating a structure example of a semiconductor device.

FIG. 12A and FIG. 12B are diagrams illustrating a structure example of a semiconductor device.

FIG. 13 is a graph showing an example of hysteresis characteristics.

FIG. 14 is a diagram illustrating crystal structures of hafnium oxide.

FIG. 15A and FIG. 15B are diagrams illustrating models of an orthorhombic crystal structure of HfZrOₓ.

FIG. 16A and FIG. 16B are equivalent circuit diagrams of a semiconductor device. FIG. 16C is a graph showing the Id—Vg characteristics of a transistor.

FIG. 17A is a timing chart for describing operation of a semiconductor device. FIG. 17B is a circuit diagram for describing operation of the semiconductor device.

FIG. 18A is a timing chart for describing operation of a semiconductor device. FIG. 18B is a circuit diagram for describing operation of the semiconductor device.

FIG. 19A is a timing chart for describing operation of a semiconductor device. FIG. 19B is a circuit diagram for describing operation of the semiconductor device.

FIG. 20A to FIG. 20C are equivalent circuit diagrams of a semiconductor device.

FIG. 21A is a block diagram illustrating a structure example of a semiconductor device. FIG. 21B is a perspective view illustrating a structure example of the semiconductor device.

FIG. 22A and FIG. 22B are perspective views illustrating examples of electronic components.

FIG. 23A to FIG. 23J are diagrams illustrating examples of electronic devices.

FIG. 24A to FIG. 24E are diagrams illustrating examples of electronic devices.

FIG. 25A to FIG. 25C are diagrams illustrating an example of an electronic device.

FIG. 26 is a diagram illustrating an example of a device for space.

### MODE FOR CARRYING OUT THE INVENTION

Embodiments and the like below will be described in detail with reference to the drawings. Note that the present invention is not limited to the following description, and it is readily understood by those skilled in the art that modes and details can be changed in various ways without departing from the spirit and scope of the present invention. Thus, the present invention should not be construed as being limited to the description in the following embodiments. Note that in the structures of the invention described below, the same portions or portions having similar functions are denoted by the same reference numerals in different drawings, and repeated description thereof is omitted in some cases.

In this specification and the like, a semiconductor device refers to a device that utilizes semiconductor characteristics, and means a circuit including a semiconductor element (a transistor, a diode, a photodiode, and the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a storage device, a display device, a light-emitting device, a lighting device, an electronic device, and the like themselves might be semiconductor devices, or might include semiconductor devices.

The position, size, range, and the like of each component illustrated in drawings and the like do not represent the actual position, size, range, and the like in some cases for easy understanding of the invention. Therefore, the disclosed invention is not necessarily limited to the position, size, range, and the like disclosed in the drawings and the like. For example, in the actual manufacturing process, a layer, a resist mask, and the like might be unintentionally reduced in size by treatment such as etching, which is not illustrated in some cases for easy understanding of the invention.

In this specification and the like, in the case where an etching step (a removal step) is performed after a resist mask is formed by a lithography method (e.g., a photolithography method, an X-ray lithography method, an electron beam lithography method, a multiphoton lithography method, an interference lithography method, or a nanoimprinting method), the resist mask is removed after the etching step, unless otherwise specified.

Especially in a plan view (also referred to as a “top view”), a perspective view, and the like, the illustration of some components might be omitted for easy understanding of the invention. The illustration of some hidden lines and the like might also be omitted.

Note that in the structures of the invention in the embodiments, the same portions or portions having similar functions are denoted by the same reference numerals in different drawings, and repeated description thereof is omitted in some cases. The same hatch pattern is used for the portions having similar functions, and the portions are not especially denoted by reference numerals in some cases. Some components are omitted in a perspective view, a plan view, and the like for easy understanding of the drawings in some cases.

Ordinal numbers such as “first” and “second” in this specification and the like are used in order to avoid confusion among components and do not denote any priority or order such as the order of steps or the stacking order. A term without an ordinal number in this specification and the like may be provided with an ordinal number in the scope of claims in order to avoid confusion among components. An ordinal number provided in this specification and the like and an ordinal number provided in the scope of claims might be different from each other. Even when a term is provided with an ordinal number in this specification and the like, the ordinal number might be omitted in the scope of claims and the like.

In this specification and the like, terms such as “electrode”, “wiring”, and “terminal” do not limit the functions of such components. For example, an “electrode” is used as part of a “wiring” in some cases, and vice versa. Furthermore, terms such as “electrode” and “wiring” also include the case where a plurality of “electrodes” and “wirings” are provided in an integrated manner, for example. As another example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, terms such as “electrode”, “wiring”, and “terminal” can sometimes be replaced with a term such as “region” depending on the case.

In this specification and the like, supply of a signal refers to supply of a predetermined potential to a wiring or the like. The term “signal” can be replaced with a term such as “potential” in some cases. A term such as “potential” can be replaced with the term “signal” in some cases. The “signal” may be a variable potential or a fixed potential. For example, it may be a power supply potential.

Note that the term “film” and the term “layer” can be interchanged with each other depending on the case or circumstances. For example, the term “conductive layer” can be replaced with the term “conductive film” in some cases. As another example, the term “insulating film” can be replaced with the term “insulating layer” in some cases.

In this specification and the like, a “capacitor element” can be, for example, a circuit element having an electrostatic capacitance value greater than 0 F, a region of a wiring having an electrostatic capacitance value greater than 0 F, parasitic capacitance, or gate capacitance of a transistor. The term “capacitor element”, “parasitic capacitance”, or “gate capacitance” can be replaced with the term “capacitor” in some cases. Conversely, the term “capacitor” can be replaced with the term “capacitor element”, “parasitic capacitance”, or “gate capacitance” in some cases. In addition, a “capacitor” (including a “capacitor” with three or more terminals) includes an insulator and a pair of conductive layers between which the insulator is interposed. Thus, the term “pair of conductive layers” of “capacitor” can be replaced with “pair of electrodes”, “pair of conductive regions”, “pair of regions”, or “pair of terminals”. The term “one of a pair of terminals” is referred to as “one terminal” or “first terminal” in some cases. The term “the other of the pair of terminals” is referred to as “the other terminal” or “second terminal” in some cases. Note that the electrostatic capacitance value can be greater than or equal to 0.05 fF and less than or equal to 10 pF, for example. As another example, the electrostatic capacitance value may be greater than or equal to 1 pF and less than or equal to 10 μF.

Functions of a “source” and a “drain” of a transistor are sometimes interchanged with each other when a transistor of the opposite conductivity type is used or when the direction of current flow is changed in circuit operation, for example. Therefore, the terms “source” and “drain” can be used interchangeably in this specification and the like.

In this specification and the like, a “gate” refers to part or the whole of a gate electrode and a gate wiring. A gate wiring refers to a wiring for electrically connecting a gate electrode of at least one transistor to another electrode or another wiring.

In this specification and the like, a “source” refers to part or the whole of a source region, a source electrode, and a source wiring. A source region refers to a region in a semiconductor layer where the resistivity is lower than or equal to a given value. A source electrode refers to a conductive layer including part connected to a source region. A source wiring refers to a wiring for electrically connecting a source electrode of at least one transistor to another electrode or another wiring.

In this specification and the like, a “drain” refers to part or the whole of a drain region, a drain electrode, and a drain wiring. A drain region refers to a region in a semiconductor layer where the resistivity is lower than or equal to a given value. A drain electrode refers to a conductive layer including part connected to a drain region. A drain wiring refers to a wiring for electrically connecting a drain electrode of at least one transistor to another electrode or another wiring.

Unless otherwise specified, a transistor described in this specification and the like is an enhancement-mode (a normally-off mode) field-effect transistor. In the case where a transistor in this specification and the like is an n-channel transistor and unless otherwise specified, the threshold voltage (also referred to as “Vth”) of the transistor is higher than 0 V. In the case where the transistor in this specification and the like is a p-channel transistor and unless otherwise specified, Vth of the transistor is lower than or equal to 0 V. Unless otherwise specified, a plurality of transistors having the same conductivity type all have the same Vth.

Unless otherwise specified, an off-state current in this specification and the like refers to a current flowing between a source and a drain (also referred to as a “drain current” or “Id”) of a transistor in an off state (also referred to as a “non-conduction state” or a “cutoff state”). Unless otherwise specified, the off state of an n-channel transistor refers to a state where the potential difference between its gate and source based on the source (also referred to as a “gate voltage” or “Vg”) is lower than the threshold voltage, and the off state of a p-channel transistor refers to a state where Vg is higher than the threshold voltage. For example, the off-state current of an n-channel transistor sometimes refers to a drain current at the time when Vg is lower than Vth.

In this specification and the like, leakage current sometimes expresses the same meaning as off-state current. Furthermore, in this specification and the like, the off-state current sometimes refers to current that flows between a source and a drain of a transistor in an off state, for example.

Unless otherwise specified, an on-state current in this specification and the like refers to Id of a transistor in an on state (also referred to as a “conduction state”). Unless otherwise specified, the on state of an n-channel transistor refers to a state where Vg is higher than or equal to Vth, and the on state of a p-channel transistor refers to a state where Vg is lower than or equal to the threshold voltage. For example, the on-state current of an n-channel transistor sometimes refers to a drain current at the time when Vg is higher than or equal to Vth.

In this specification and the like, a high power supply potential VDD (hereinafter also simply referred to as “VDD” or a “potential H”) is a power supply potential higher than a low power supply potential VSS. The low power supply potential VSS (hereinafter also simply referred to as “VSS” or a “potential L”) is a power supply potential lower than the high power supply potential VDD. In addition, a ground potential GND (hereinafter also simply referred to as “GND”) can be used as VDD or VSS. For example, VSS is a potential lower than GND when VDD is GND, and VDD is a potential higher than GND when VSS is GND. Note that in this specification and the like, VSS is a reference potential unless otherwise specified.

A “voltage” usually refers to a potential difference between a given potential and a reference potential (e.g., a ground potential or a source potential). A “potential” is a relative value, and a potential supplied to a wiring or the like changes depending on the reference potential in some cases. Therefore, the terms “voltage” and “potential” can be replaced with each other in some cases.

In this specification and the like, terms for describing arrangement, such as “over”, “under”, “above”, and “below”, are sometimes used for convenience to describe the positional relationship between components with reference to drawings. The positional relationship between components changes as appropriate in accordance with a direction in which each component is described. Thus, without limitation to terms described in this specification and the like, the description can be changed appropriately depending on the situation. For example, the expression “an insulating layer positioned over a conductive layer” can be replaced with the expression “an insulating layer positioned under a conductive layer” when the direction of a drawing illustrating these components is rotated by 180°. For example, the expression “an insulating layer positioned over an opening” includes “an insulating layer positioned on a side surface of an opening” in some cases.

The term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and does not exclude the state where the electrode B is formed under the insulating layer A or the state where the electrode B is formed on the right (or left) side of the insulating layer A.

The terms “adjacent” and “close” in this specification and the like do not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In the drawings and the like for this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals.

### Embodiment 1

A semiconductor device 100A of one embodiment of the present invention will be described in this embodiment.

### <<Structure Example of Semiconductor Device 100A>>

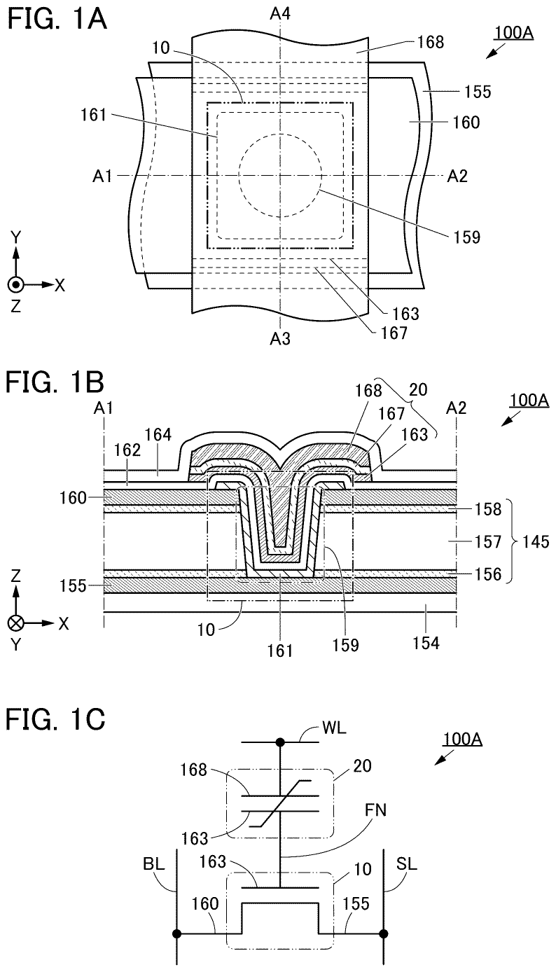

The semiconductor device 100A includes a transistor 10 and a capacitor element 20 over the transistor 10. FIG. 1A is a plan view of the semiconductor device 100A. FIG. 1B is a cross-sectional view of a portion indicated by the dashed-dotted line A1-A2 in FIG. 1A, which is seen from the Y direction. Note that some components are omitted in the plan view in FIG. 1A for clarity of the drawing.

FIG. 1C illustrates an equivalent circuit diagram of the semiconductor device 100A. In FIG. 1C, one of a source and a drain of the transistor 10 is electrically connected to a wiring SL, and the other thereof is electrically connected to a wiring BL. One electrode of the capacitor element 20 is electrically connected to a wiring WL. A gate of the transistor 10 is electrically connected to the other electrode of the capacitor element 20. The semiconductor device 100A functions as a storage circuit (also referred to as a “storage element” or a “memory cell”). Note that FIG. 1C is an equivalent circuit diagram of the case where the capacitor element 20 includes a ferroelectric.

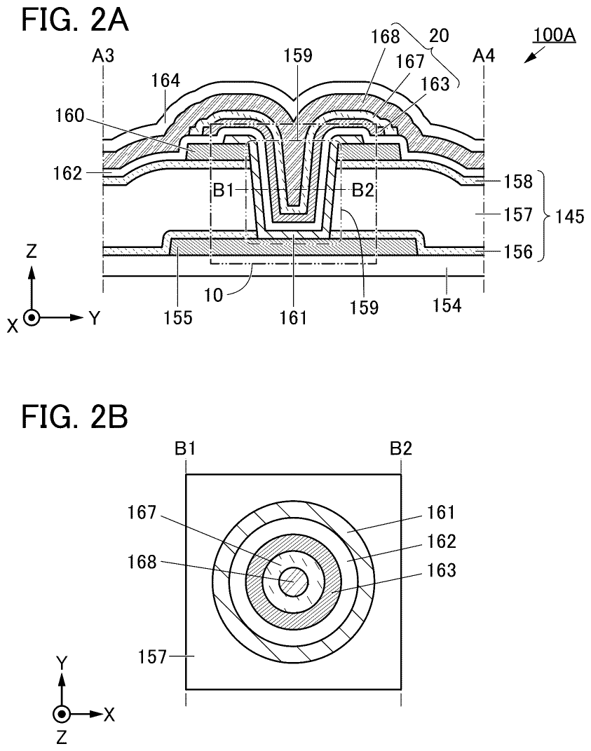

FIG. 2A is a cross-sectional view of a portion indicated by the dashed-dotted line A3-A4 in FIG. 1A, which is seen from the X direction. FIG. 2B is an enlarged cross-sectional view of a portion indicated by the dashed-dotted line B1-B2 in FIG. 2A, which is seen from the Z direction.

The semiconductor device 100A of one embodiment of the present invention includes a conductive layer 155 over an insulating layer 154. The semiconductor device 100A includes an insulating layer 156 over the conductive layer 155, an insulating layer 157 over the insulating layer 156, and an insulating layer 158 over the insulating layer 157. Note that the insulating layer 156, the insulating layer 157, and the insulating layer 158 are collectively referred to as an insulating layer 145 or a spacer layer in some cases. A conductive layer 160 is provided over the insulating layer 158. Note that in the semiconductor device 100A described in this embodiment, the conductive layer 155 and the conductive layer 160 each include a region extending in the X direction. Note that the direction in which the conductive layer 155 extends and the direction in which the conductive layer 160 extends may be different from each other. For example, the direction in which the conductive layer 155 extends and the direction in which the conductive layer 160 extends may be orthogonal to each other.

In a region overlapping with part of the conductive layer 155, an opening 159 is provided in the conductive layer 160, the insulating layer 158, the insulating layer 157, and the insulating layer 156 (see FIG. 1A, FIG. 1B, and FIG. 2A). The semiconductor device 100A includes a semiconductor layer 161 covering the opening 159. The semiconductor layer 161 is provided to cover the opening 159 in the plan view. The semiconductor layer 161 includes a region overlapping with a bottom portion of the opening 159 and a region overlapping with a side surface of the opening 159. That is, the semiconductor layer 161 includes a region in contact with a side surface of the insulating layer 145. In FIG. 1B, the semiconductor layer 161 includes a region in contact with a side surface of the insulating layer 156, a region in contact with a side surface of the insulating layer 157, and a region in contact with a side surface of the insulating layer 158.

The semiconductor layer 161 includes a region in contact with the conductive layer 155 and a region in contact with the conductive layer 160. That is, part of the semiconductor layer 161 is electrically connected to the conductive layer 155, and another part of the semiconductor layer 161 is electrically connected to the conductive layer 160.

An insulating layer 162 is provided over the insulating layer 158, the conductive layer 160, and the semiconductor layer 161. A conductive layer 163 is provided over the insulating layer 162. The conductive layer 163 includes a region overlapping with the opening 159 in the plan view. The conductive layer 163 includes a region that overlaps, in the opening 159, with the side surface of the opening 159 (the side surface of the insulating layer 145) with the insulating layer 162 and the semiconductor layer 161 therebetween (see FIG. 1B, FIG. 2A, and FIG. 2B). In the cross-sectional view of FIG. 2B, an insulating layer 167, the conductive layer 163, the insulating layer 162, and the semiconductor layer 161 are concentrically arranged with a conductive layer 168 as the center.

The thickness of the semiconductor layer 161 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm. The thickness of the insulating layer 162 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulating layer 162 may have a region with the above-described thickness.

The insulating layer 167 is provided over the conductive layer 163, and the conductive layer 168 is provided over the insulating layer 167. As illustrated in FIG. 2A, the insulating layer 167 may include a region extending beyond an end portion of the conductive layer 163. The conductive layer 168 includes a region extending beyond the end portion of the conductive layer 163 and an end portion of the insulating layer 167. In the semiconductor device 100A described in this embodiment, the conductive layer 168 includes a region extending in the Y direction. An insulating layer 164 is provided over the insulating layer 162 and the conductive layer 168.

In general, a capacitor element is formed with a pair of electrodes with a dielectric interposed therebetween. In the semiconductor device 100A, at least part of the conductive layer 168 functions as one electrode of the capacitor element 20, and at least part of the conductive layer 163 functions as the other electrode of the capacitor element 20. A region where the conductive layer 163 and the conductive layer 168 overlap with each other with the insulating layer 167 therebetween functions as the capacitor element 20. In the semiconductor device 100A, part of the capacitor element 20 is provided in the opening 159. Part of the capacitor element 20 overlaps with the side surface of the opening 159. In other words, the capacitor element 20 includes a region that overlaps, in the opening 159, with the side surface of the insulating layer 145 with the insulating layer 162 and the semiconductor layer 161 therebetween.

In the semiconductor device 100A of one embodiment of the present invention, the transistor 10 and the capacitor element 20 are provided to overlap with each other. When the transistor 10 and the capacitor element 20 are provided to overlap with each other, the area occupied by the semiconductor device 100A can be reduced.

The capacitance value (the electrostatic capacitance value) of the capacitor element 20 is proportional to the area of a region where the conductive layer 163 and the conductive layer 168 overlap with each other with the insulating layer 167 therebetween. When at least part of the capacitor element 20 is provided in the opening 159, a reduction in electrostatic capacitance value due to a reduction in the area occupied by the semiconductor device 100A can be prevented. That is, a reduction in electrostatic capacitance value due to a reduction in the area occupied by the capacitor element 20 can be prevented. In addition, when at least part of the capacitor element 20 is provided in the opening 159, a necessary electrostatic capacitance value can be ensured even when the area occupied by the semiconductor device 100A is reduced. That is, a necessary electrostatic capacitance value can be ensured even when the area occupied by the capacitor element 20 is reduced.

### <Transistor 10>

The conductive layer 155 includes a region functioning as one of a source electrode and a drain electrode of the transistor 10. The conductive layer 160 includes a region functioning as the other of the source electrode and the drain electrode of the transistor 10. For example, in the case where the conductive layer 155 includes a region functioning as the drain electrode of the transistor 10, the conductive layer 160 includes a region functioning as the source electrode of the transistor 10.

The conductive layer 155 functions as at least part of the wiring SL. The conductive layer 160 functions as at least part of the wiring BL. The conductive layer 168 functions as at least part of the wiring WL. The conductive layer 163 functions as a gate electrode of the transistor 10 and also functions as the other electrode of the capacitor element 20. Note that the wiring SL and the wiring BL can be interchanged with each other. The conductive layer 155 may function as at least part of the wiring BL, and the conductive layer 160 may function as at least part of the wiring SL.

The semiconductor layer 161 includes a region functioning as a semiconductor layer where a channel of the transistor 10 is formed (a semiconductor layer including a channel formation region). The insulating layer 162 includes a region functioning as a gate insulating layer. The channel of the transistor 10 is formed in the semiconductor layer 161 between a region of the semiconductor layer 161 that is in contact with the conductive layer 155 and a region of the semiconductor layer 161 that is in contact with the conductive layer 160. In other words, the transistor 10 is provided in a region including the opening 159.

The source electrode and the drain electrode of the transistor 10 are placed in the Z direction. That is, the source and the drain of the transistor 10 are placed at different levels. In other words, the source and the drain of the transistor 10 are placed at different positions in the Z direction. Such a transistor is also referred to as a “vertical-channel transistor”, a “vertical transistor”, or a “VFET (Vertical Field Effect Transistor)”.

The source electrode and the drain electrode of the vertical-channel transistor of one embodiment of the present invention are placed in the Z direction. That is, the channel formation region, the source region, and the drain region are placed in the Z direction. The area occupied by the vertical-channel transistor can be made smaller than that occupied by a conventional transistor in which the channel formation region, the source region, and the drain region are provided separately on the X-Y plane.

Thus, when the vertical-channel transistor is used in a semiconductor device, the area occupied by the semiconductor device can be reduced. When the vertical-channel transistor is used in a semiconductor device, high integration of the semiconductor device can be achieved. For example, it is possible to increase the storage capacity per unit area of a storage device including the semiconductor device.

The channel length of a conventional transistor is determined by the light exposure limit of photolithography. The channel length of the vertical-channel transistor can be determined by the thickness of the insulating layer 145. Thus, the transistor 10 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). This increases the on-state current of the transistor 10 to improve frequency characteristics. The use of a vertical-channel transistor can provide a semiconductor device with high operation speed.

Note that a channel length L, a channel width W, and the like of the transistor 10 will be described in detail later.

<capacitor Element 20>

As described above, the region where the conductive layer 163 and the conductive layer 168 overlap with each other with the insulating layer 167 therebetween functions as the capacitor element 20. A ferroelectric is preferably used for the insulating layer 167. The ferroelectric has a property of causing internal dielectric polarization by application of an electric field from the outside and maintaining the polarization even after the electric field is made zero. Thus, with the use of a capacitor element (also referred to as a “ferroelectric capacitor”) that includes this material as a dielectric, a nonvolatile storage element can be achieved.

The thickness of the insulating layer 167 is preferably less than or equal to 100 nm, further preferably less than or equal to 50 nm, still further preferably less than or equal to 20 nm, yet still further preferably less than or equal to 10 nm (typically, greater than or equal to 2 nm and less than or equal to 9 nm). The thickness of the insulating layer 167 is preferably greater than or equal to 8 nm and less than or equal to 12 nm, for example.

Note that a nonvolatile storage element using a ferroelectric is referred to as a “ferroelectric memory” or the like in some cases. Details of the ferroelectric will be described later.

A material with a high relative dielectric constant (also referred to as a “high-k material”) may be used for the insulating layer 167. When a high-k material is used for the insulating layer 167, the electrostatic capacitance needed for the capacitor element 20 can be ensured and the insulating layer 167 can have a large thickness. The insulating layer 167 with a large thickness increases the withstand voltage between the conductive layer 163 and the conductive layer 168 to inhibit electrostatic breakdown. As a result, the reliability of the capacitor element 20 is improved. Thus, the reliability of the semiconductor device including the capacitor element 20 is improved.

### <Materials Forming Semiconductor Device>

Examples of materials that can be used for the semiconductor device 100A of one embodiment of the present invention are described below.

### [Substrate]

In the case where the semiconductor device 100A is provided over a substrate, there is no particular limitation on a material used for the substrate. The material is determined in accordance with the purpose in consideration of whether it has a light-transmitting property, heat resistance high enough to withstand heat treatment, or the like. For example, an insulator substrate, a semiconductor substrate, or a conductor substrate may be used. As the insulator substrate, for example, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used. Alternatively, a semiconductor substrate, a flexible substrate, a resin substrate, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. Another example is a semiconductor substrate in which an insulator region is included in the semiconductor substrate described above, e.g., an SOI (Silicon On Insulator) substrate. The semiconductor substrate may be a single crystal semiconductor or polycrystalline semiconductor substrate.

Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator.

For the material of the flexible substrate, the resin substrate, or the like, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example.

When the above-described material is used for the substrate, a lightweight semiconductor device including the transistor 10 can be provided. Furthermore, when the above-described material is used for the substrate, a shock-resistant semiconductor device can be provided. Moreover, when the above-described material is used for the substrate, a semiconductor device that is less likely to be broken can be provided.

Alternatively, these substrates provided with elements may be used. Examples of the element provided for the substrate include a capacitor element, a resistor element, a switching element, a light-emitting element, and a storage element.

### [Insulating Layer]

An insulating oxide, an insulating nitride, an insulating oxynitride, an insulating nitride oxide, an insulating metal oxide, an insulating metal oxynitride, an insulating metal nitride oxide, or the like can be used for the insulating layer. For example, a single layer or a stacked layer of an insulating material selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like is used as the insulating layer. A material in which two or more materials selected from an oxide material, a nitride material, an oxynitride material, and a nitride oxide material are mixed may be used.

Note that in this specification and the like, a nitride oxide refers to a material that contains more nitrogen than oxygen. An oxynitride refers to a material that contains more oxygen than nitrogen. The content of each element can be measured by Rutherford backscattering spectrometry (RBS), for example.

As miniaturization and high integration of transistors progress, a problem such as leakage current may arise because of a thinner gate insulating layer. When a high-k material (a high dielectric constant material or a material with a high relative dielectric constant) is used for an insulating layer functioning as the gate insulating layer, a gate potential during operation of the transistor can be reduced while the physical thickness is maintained. A substance with a high dielectric constant, such as lead zirconate titanate (PZT), strontium titanate (SrTiO₃), or (Ba, Sr)TiO₃ (BST), can be used for the insulating layer in some cases. By contrast, when a material with a low relative dielectric constant is used for the insulating layer functioning as an interlayer film, parasitic capacitance generated between wirings can be reduced. Thus, a material is preferably selected depending on the function needed for the insulating layer.

Examples of materials with a high relative dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of materials with a low relative dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

There is no particular limitation on the formation method of the insulating material, and a variety of formation methods such as an evaporation method, an atomic layer deposition (ALD) method, a chemical vapor deposition (CVD) method, a sputtering method, and a spin coating method can be employed.

For example, it is preferable that the insulating layer 154 and the insulating layer 164 be formed using an insulating material through which impurities are less likely to pass. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Examples of insulating materials through which impurities are less likely to pass, include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material through which impurities are less likely to pass is used for the insulating layer 154, impurity diffusion from under the insulating layer 154 can be inhibited, and the reliability of the transistor 10 can be improved. This means that the reliability of the semiconductor device 100A including the transistor 10 can be improved. When the insulating material through which impurities are less likely to pass is used for the insulating layer 164, impurity diffusion from above the insulating layer 164 can be inhibited, and the reliability of the transistor 10 can be improved. This means that the reliability of the semiconductor device 100A including the transistor 10 can be improved.

As the insulating layer, an insulating layer capable of functioning as a planarization layer may be used. Examples of materials capable of functioning as the planarization layer include an acrylic resin, polyimide, an epoxy resin, polyamide, polyimide amide, a siloxane resin, a benzocyclobutene resin, a phenol resin, and precursors of these resins. Besides the above organic materials, a low-k material (a low dielectric constant material or a material with a low relative dielectric constant), a siloxane resin, PSG (phosphosilicate glass), BPSG (borophosphosilicate glass), or the like can also be used. Note that a plurality of insulating layers formed of these materials may be stacked.

Note that the siloxane resin corresponds to a resin including a Si—O—Si bond formed using a siloxane-based material as a starting material. The siloxane resin may include an organic group (e.g., an alkyl group or an aryl group) or a fluoro group as a substituent. In addition, the organic group may include a fluoro group.

As the insulating layer 167 functioning as a dielectric of the capacitor element 20, a three-layer insulating layer (also referred to as “ZAZ”) including aluminum oxide sandwiched between two zirconium oxide layers may be used. ZAZ is a material with a high relative dielectric constant, and when ZAZ is used as a dielectric of the capacitor element 20, the area occupied by the capacitor element 20 can be reduced.

As described above, a material that can have ferroelectricity is preferably used for the insulating layer 167 so that the capacitor element 20 function as a ferroelectric capacitor.

As the material that can have ferroelectricity, for example, hafnium oxide is preferably used. Alternatively, as the material that can have ferroelectricity, a metal oxide such as zirconium oxide or HfZrO_{X} (hereinafter also referred to as “HfZrOx”, X is a real number greater than 0) may be used. Alternatively, as the material that can have ferroelectricity, a material in which an element J1 (the element J1 here is one or more selected from zirconium (Zr), silicon (Si), aluminum (Al), gadolinium (Gd), yttrium (Y), lanthanum (La), strontium (Sr), and the like) is added to hafnium oxide may be used.

Here, the atomic ratio of a hafnium atom to the element J1 can be set as appropriate. For example, the atomic ratio of a hafnium atom to a zirconium atom may be 1:1 or in the neighborhood thereof. Alternatively, as the material that can have ferroelectricity, a material in which an element J2 (the element J2 here is one or more selected from hafnium (Hf), silicon (Si), aluminum (Al), gadolinium (Gd), yttrium (Y), lanthanum (La), strontium (Sr), and the like) is added to zirconium oxide, or the like can be used. The atomic ratio of a zirconium atom to the element J2 can be set as appropriate; the atomic ratio of a zirconium atom to the element J2 is, for example, 1:1 or in the neighborhood thereof. As the material that can have ferroelectricity, a piezoelectric ceramic having a perovskite structure, such as lead titanate (PbTiOx), barium strontium titanate (BST), strontium titanate, lead zirconate titanate (PZT), strontium bismuth tantalate (SBT), bismuth ferrite (BFO), or barium titanate, may be used.

As the material that can have ferroelectricity, scandium aluminum nitride (Al₁₋ₐScₐN_{b} (a is a real number greater than 0 and less than 0.5, and b is 1 or an approximate value thereof), hereinafter simply referred to as “AlScN” in some cases), Al—Ga—Sc nitride, Ga-Sc nitride, or the like can be used. As the material that can have ferroelectricity, a metal nitride containing an element M1, an element M2, and nitrogen can also be used. Here, the element M1 is one or more selected from aluminum (Al), gallium (Ga), indium (In), and the like. The element M2 is one or more selected from boron (B), scandium (Sc), yttrium (Y), lanthanoids (lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu)), actinoids (15 elements from actinium (Ac) to lawrencium (Lr)), titanium (Ti), zirconium (Zr), hafnium (Hf), vanadium (V), niobium (Nb), tantalum (Ta), chromium (Cr), and the like. Note that the atomic ratio of the element M1 to the element M2 can be set as appropriate. A metal oxide containing the element M1 and nitrogen has ferroelectricity in some cases even though not containing the element M2. As the material that can have ferroelectricity, a material in which an element M3 is added to the above metal nitride can be used. Note that the element M3 is one or more selected from magnesium (Mg), calcium (Ca), strontium (Sr), zinc (Zn), cadmium (Cd), and the like. Here, the atomic ratio of the element M1, the element M2, and the element M3 can be set as appropriate. Since the above metal nitride contains at least a Group 13 element and nitrogen, which is a Group 15 element, the metal nitride is referred to as a ferroelectric of Group 13-15, a ferroelectric of a Group 13 nitride, or the like in some cases.

As the material that can have ferroelectricity, a perovskite-type oxynitride such as SrTaO₂N or BaTaO₂N, GaFeO₃ with a k-alumina-type structure, or the like can be used.

The material that can have ferroelectricity can be, for example, a mixture or a compound formed of a plurality of materials selected from the above-listed materials. Alternatively, the material that can have ferroelectricity can have a stacked-layer structure of a plurality of materials selected from the above-listed materials. The above-listed materials may change their crystal structures or characteristics according to a variety of processes and the like as well as film formation conditions; in this specification and the like, not only a material that exhibits ferroelectricity but also a material that can have ferroelectricity is referred to as a ferroelectric. In other words, the term “ferroelectric” in this specification and the like includes both a material that exhibits ferroelectricity and a material that can have ferroelectricity.

Note that in this specification and the like, a ferroelectric is referred to as a “ferroelectric material” in some cases. In this specification and the like, a layered ferroelectric is referred to as a “ferroelectric layer” in some cases. In this specification and the like, a device including a ferroelectric is referred to as a “ferroelectric device” in some cases.

A material containing hafnium oxide or hafnium oxide and zirconium oxide (typically, HfZrOx) is suitable as a ferroelectric because the material can have ferroelectricity even when having a thickness of several nanometers.

Scandium aluminum nitride (AlScN), which can be formed by a sputtering method, is suitable as a ferroelectric because the impurity concentration in the film can be reduced or a dense film can be formed. In the case where scandium aluminum nitride (AlScN) is used as a ferroelectric, achievement of a highly reliable ferroelectric can be expected.

The thickness of a ferroelectric layer can be less than or equal to 100 nm, preferably less than or equal to 50 nm, further preferably less than or equal to 20 nm, and still further preferably less than or equal to 10 nm (typically, greater than or equal to 2 nm and less than or equal to 9 nm). For example, the thickness of the ferroelectric layer is preferably greater than or equal to 8 nm and less than or equal to 12 nm. When the thickness of the ferroelectric layer is in the above range, ferroelectricity can be exhibited with a thin film.

A reduction in the thickness of the ferroelectric layer facilitates miniaturization of a ferroelectric capacitor including the ferroelectric layer. This facilitates miniaturization of a semiconductor device that includes a ferroelectric capacitor and a semiconductor element such as a transistor in combination. That is, a semiconductor device that occupies a small area can be easily achieved.

In the case where HfZrOx is used as a ferroelectric, an ALD method, specifically, a thermal ALD method is preferably used for formation. In the case where a ferroelectric is formed by a thermal ALD method, it is suitable to use a material that does not contain hydrocarbon (also referred to as Hydro Carbon or HC) for a precursor. When one or both of hydrogen and carbon are contained in the ferroelectric, crystallization of the ferroelectric might be hindered. Thus, the precursor that does not contain hydrocarbon is preferably used as described above to reduce the concentration(s) of one or both of hydrogen and carbon in the ferroelectric. Examples of the precursor that does not contain hydrocarbon include a chlorine-based material. In the case where a material containing hafnium oxide and zirconium oxide (HfZrOx) is used as the ferroelectric, HfCl₄ and/or ZrCl₄ are/is used as the precursor. On the other hand, a dopant (typically, silicon, carbon, or the like) for controlling the polarization state may be added to the ferroelectric. In that case, a formation method using a material containing hydrocarbon as a precursor may be used as a way of adding carbon as a dopant.

In the case where a layer including a ferroelectric is formed, impurities in the layer, at least one or more of hydrogen, hydrocarbon, and carbon here, are thoroughly removed, whereby a highly purified intrinsic ferroelectric layer can be formed. Note that the highly purified intrinsic ferroelectric layer and a highly purified intrinsic oxide semiconductor described later are highly compatible with each other in the manufacturing process. Thus, a semiconductor device with high productivity can be provided.

The impurity concentration in a ferroelectric is preferably low. In particular, the concentrations of hydrogen (H) and carbon (C) are preferably as low as possible. Specifically, the hydrogen concentration in the ferroelectric is preferably lower than or equal to 5×10²⁰ atoms/cm³, further preferably lower than or equal to 1×10²⁰ atoms/cm³. The carbon concentration in the ferroelectric is preferably lower than or equal to 5×10¹⁹ atoms/cm³, further preferably lower than or equal to 1×10¹⁹atoms/cm³.

In the case where HfZrOx is used a ferroelectric, a film of hafnium oxide and a film of zirconium oxide are preferably formed alternately by an ALD method so as to have a composition of 1:1.

In the case where a ferroelectric is formed by an ALD method, H₂O or O₃ can be used as an oxidizer. However, the oxidizer in the ALD method is not limited thereto. For example, the oxidizer in the ALD method may contain any one or more selected from O₂, O₃, N₂O, NO₂, H₂O, and H₂O₂.

In particular, the ferroelectric layer preferably has an orthorhombic crystal structure because ferroelectricity is easily exhibited. Note that the ferroelectric layer may have another crystal structure in addition to the orthorhombic crystal structure. For example, the ferroelectric layer may have any one or more crystal structures selected from a cubic crystal structure, a tetragonal crystal structure, and a monoclinic crystal structure in addition to the orthorhombic crystal structure. Note that a layer for improving crystallinity may be formed before the ferroelectric layer is formed. For example, in the case where HfZrOx is used as the ferroelectric layer, a metal oxide such as hafnium oxide or zirconium oxide, hafnium, or zirconium can be used for the layer for improving crystallinity.

In the case where scandium aluminum nitride is used as the ferroelectric layer, the ferroelectric layer preferably has a hexagonal crystal structure. Note that the ferroelectric layer may have another crystal structure in addition to the hexagonal crystal structure. For the layer for improving crystallinity, a metal nitride such as aluminum nitride or scandium nitride, aluminum, or scandium is preferably used.

Note that the layer for improving crystallinity may be formed after the ferroelectric layer is formed. Alternatively, the ferroelectric layer may have a composite structure of an amorphous structure and a crystal structure.

### [Conductive Layer]

As a conductive material that can be used for conductive layers such as various wirings and electrodes included in the semiconductor device, a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), ruthenium (Ru), and the like; an alloy containing the above metal element as a component; an alloy containing the above metal elements in combination; or the like can be used.

For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. A semiconductor having high electrical conductivity, typified by polycrystalline silicon containing an impurity element such as phosphorus, or silicide such as nickel silicide may be used. There is no particular limitation on the formation method of the conductive material, and a variety of formation methods such as an evaporation method, an ALD method, a CVD method, a sputtering method, and a spin coating method can be employed.

A Cu—X alloy (X is Mn, Ni, Cr, Fe, Co, Mo, Ta, or Ti) may be used as the conductive material. A layer formed using a Cu—X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive material.

As the conductive material that can be used for the conductive layer, a conductive material containing oxygen, such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added, can be used. A conductive material containing nitrogen, such as titanium nitride, tantalum nitride, or tungsten nitride, can also be used. The conductive layer can have a stacked-layer structure with an appropriate combination of a conductive material containing oxygen, a conductive material containing nitrogen, and a material containing the above-described metal element.

For example, the conductive layer can have a single-layer structure of an aluminum layer including silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure of a titanium layer, an aluminum layer stacked over the titanium layer, and a titanium layer further stacked thereover.

Furthermore, a plurality of conductive layers formed with the above conductive materials may be stacked and used. For example, the conductive layer may have a stacked-layer structure in which a material containing the above-described metal element is combined with a conductive material containing oxygen. It is also possible to employ a stacked-layer structure in which a material containing the above-described metal element is combined with a conductive material containing nitrogen. It is also possible to employ a stacked-layer structure in which a material containing the above-described metal element is combined with a conductive material containing oxygen and a conductive material containing nitrogen.

For example, the conductive layer may have a three-layer structure in which a conductive layer containing copper is stacked over a conductive layer containing oxygen and at least one of indium and zinc, and a conductive layer containing oxygen and at least one of indium and zinc is stacked thereover. In that case, a side surface of the conductive layer containing copper is preferably covered with the conductive layer containing oxygen and at least one of indium and zinc. Alternatively, a plurality of conductive layers containing oxygen and at least one of indium and zinc may be stacked and used as the conductive layer, for example.

In the case where the capacitor element 20 functions as a ferroelectric capacitor, a material that easily causes polarization in the insulating layer 167 is preferably used for the conductive layer 163 and the conductive layer 168, which are in contact with the insulating layer 167 that is a ferroelectric. For example, titanium nitride is preferably used for the conductive layer 163 and the conductive layer 168.

### [Semiconductor Layer]

For the semiconductor layer 161, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, or a nitride semiconductor may be used. As the compound semiconductor, an organic substance having semiconductor characteristics or a metal oxide having semiconductor characteristics (also referred to as an oxide semiconductor) can be used. These semiconductor materials may contain an impurity as a dopant.

For the semiconductor layer 161, single crystal silicon, polycrystalline silicon, microcrystalline silicon, and amorphous silicon may be used, for example. As the polycrystalline silicon, for example, low-temperature polysilicon (LTPS) may be used.

The transistor including amorphous silicon in the semiconductor layer 161 can be formed over a large glass substrate, and can be manufactured at low cost. The transistor including polycrystalline silicon in the semiconductor layer 161 has high field-effect mobility and enables high-speed operation. The transistor including microcrystalline silicon in the semiconductor layer 161 has higher field-effect mobility and enables higher speed operation than the transistor including amorphous silicon.

The semiconductor layer 161 may include a layered substance functioning as a semiconductor. The layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MOS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

An oxide semiconductor has a band gap of 2 eV or more; thus, a transistor using an oxide semiconductor, which is a kind of metal oxide, for a semiconductor layer where a channel is formed (also referred to as an “OS transistor”) has an extremely low off-state current. Thus, the power consumption of a semiconductor device including an OS transistor can be reduced. The OS transistor operates stably even in a high-temperature environment and has small change in characteristics. For example, the off-state current hardly increases even in a high-temperature environment. Specifically, the off-state current hardly increases even at an environmental temperature higher than or equal to room temperature and lower than or equal to 200° C. Furthermore, the on-state current of the OS transistor is unlikely to decrease even in a high-temperature environment. Therefore, the semiconductor device including the OS transistor can operate stably and have high reliability even in a high-temperature environment.

Note that in this embodiment and the like, an OS transistor is preferably used as the transistor 10. Since an OS transistor has a high breakdown voltage between the source and the drain, the channel length can be shortened. The on-state current can be increased accordingly. Thus, the OS transistor is suitably used as a vertical-channel transistor.

Examples of the metal oxide that can be used for the semiconductor layer of the OS transistor include indium oxide, gallium oxide, and zinc oxide. The metal oxide preferably contains at least indium (In) or zinc (Zn). The metal oxide preferably contains two or three selected from indium, an element M, and zinc. The element Mis a metal element or metalloid element that has a high bonding energy with oxygen, such as a metal element or metalloid element whose bonding energy with oxygen is higher than that of indium, for example.

Specific examples of the element M include aluminum, gallium, tin, yttrium, titanium, vanadium, chromium, manganese, iron, copper, cobalt, nickel, zirconium, molybdenum, hafnium, tantalum, tungsten, lanthanum, cerium, neodymium, magnesium, calcium, strontium, barium, beryllium, boron, silicon, germanium, and antimony. The element M contained in the metal oxide is preferably one or more kinds of the above elements, further preferably one or more kinds selected from aluminum, gallium, tin, and yttrium, and still further preferably gallium. Note that in this specification and the like, a metal element and a metalloid element may be collectively referred to as a “metal element”, and a “metal element” in this specification and the like may refer to a metalloid element.

Examples of the metal oxide that can be used for the semiconductor layer of the OS transistor include indium oxide (In oxide), indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as “GZO”), aluminum zinc oxide (Al—Zn oxide, also referred to as “AZO”), indium aluminum zinc oxide (In—Al—Zn oxide, also referred to as “IAZO”), indium tin zinc oxide (In—Sn—Zn oxide), indium titanium zinc oxide (In—Ti—Zn oxide), indium gallium zinc oxide (In—Ga—Zn oxide, also referred to as “IGZO”), indium gallium tin zinc oxide (In—Ga—Sn—Zn oxide, also referred to as “IGZTO”), and indium gallium aluminum zinc oxide (In—Ga—Al—Zn oxide, also referred to as “IGAZO” or “IAGZO”). Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table. Alternatively, the metal oxide may contain, in addition to indium, one or more kinds of metal elements with large period numbers in the periodic table. The larger the overlap between orbits of metal elements is, the more likely it is that the metal oxide will have high carrier conductivity. Thus, a transistor containing a metal element with a large period number in the periodic table can have high field-effect mobility in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of metal elements in the main elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of metal elements in the main elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

Electrical characteristics and reliability of a transistor vary depending on the composition of the metal oxide used for the semiconductor layer. Therefore, by changing the composition of the metal oxide in accordance with the electrical characteristics and reliability required for the transistor, the semiconductor device can have both excellent electrical characteristics and high reliability.

In the case where In—Zn oxide is used for the semiconductor layer of the OS transistor, a metal oxide in which the atomic ratio of indium is higher than or equal to the atomic ratio of zinc may be used. For example, a metal oxide in which the atomic ratio of indium and zinc is In:Zn=1:1, In:Zn=2:1, In:Zn=3:1, In:Zn=4:1, In:Zn=5:1, In:Zn=7:1, In:Zn=10:1, or in the neighborhood thereof may be used.

In the case where In—Sn oxide is used for the semiconductor layer of the OS transistor, a metal oxide in which the atomic ratio of indium is higher than or equal to the atomic ratio of tin may be used. For example, a metal oxide in which the atomic ratio of indium and tin is In: Sn=1:1, In:Sn=2:1, In:Sn=3:1, In:Sn=4:1, In:Sn=5:1, In:Sn=7:1, In:Sn=10:1, or in the neighborhood thereof may be used.

In the case where In—Sn—Zn oxide is used for the semiconductor layer of the OS transistor, a metal oxide in which the atomic ratio of indium is higher than the atomic ratio of tin may be used. It is further preferable to use a metal oxide in which the atomic ratio of zinc is higher than the atomic ratio of tin. For example, a metal oxide in which the atomic ratio of indium, tin, and zinc is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, In:Sn:Zn=40:1:10, or in the neighborhood thereof may be used.

In the case where In—Al—Zn oxide is used for the semiconductor layer of the OS transistor, a metal oxide in which the atomic ratio of indium is higher than the atomic ratio of aluminum may be used. It is further preferable to use a metal oxide in which the atomic ratio of zinc is higher than the atomic ratio of aluminum. For example, a metal oxide in which the atomic ratio of indium, aluminum, and zinc is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, In:Al:Zn=40:1:10, or in the neighborhood thereof may be used.

In the case where In—Ga—Zn oxide is used for the semiconductor layer of the OS transistor, a metal oxide in which the atomic ratio of indium is higher than the atomic ratio of gallium may be used. It is further preferable to use a metal oxide in which the atomic ratio of zinc is higher than the atomic ratio of gallium. For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof may be used for the semiconductor layer.

In the case where In—M—Zn oxide is used for the semiconductor layer of the OS transistor, a metal oxide in which the atomic ratio of indium is higher than the atomic ratio of the element M may be used. It is further preferable to use a metal oxide in which the atomic ratio of zinc is higher than the atomic ratio of the element M. For example, a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or in the neighborhood thereof may be used for the semiconductor layer.

In the case where In—M—Zn oxide is used for the semiconductor layer, a metal oxide in which the atomic ratio of indium, the element M, and zinc is In:M:Zn=1:3:2 [atomic ratio] or in the neighborhood thereof, In:M:Zn=1:3:4 [atomic ratio] or in the neighborhood thereof, In:M:Zn=1:1:0.5 [atomic ratio] or in the neighborhood thereof, In:M:Zn=1:1:1 [atomic ratio] or in the neighborhood thereof, In:M:Zn=1:1:1.2 [atomic ratio] or in the neighborhood thereof, or In:M:Zn=1:1:2 [atomic ratio] or in the neighborhood thereof may be used. Note that a composition in the neighborhood includes the range of ±30% of an intended atomic ratio. Gallium is preferably used as the element M.

In the case where a plurality of metal elements are contained as the element M, the sum of the atomic ratios of the metal elements can be the atomic ratio of the element M. In the case of In—Ga—Al—Zn oxide in which gallium and aluminum are contained as the element M, for example, the sum of the atomic ratio of gallium and the atomic ratio of aluminum can be the atomic ratio of the element M. The atomic ratio of indium, the element M, and zinc is preferably within the ranges given above.

It is preferable to use a metal oxide in which the proportion of the number of indium atoms in the total number of atoms of metal elements in the main elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case where In—M—Zn oxide is used for the semiconductor layer, the proportion of the number of indium atoms in the total number of atoms of indium, the element M, and zinc is preferably within the ranges given above.

As described above, by increasing the proportion of the number of indium atoms in the total number of atoms of metal elements in the main elements contained in the metal oxide, the field-effect mobility of the transistor can be increased. With the use of such a transistor, a semiconductor device capable of high-speed operation can be fabricated. Furthermore, the area occupied by the semiconductor device can be reduced.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

The metal oxide can be formed by a sputtering method, a CVD method such as a metal organic chemical vapor deposition (MOCVD) method, an ALD method, or the like.

Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately higher than or equal to 40% and lower than or equal to 90% of the atomic ratio of zinc contained in the target.

Note that when a film of the metal oxide is formed by a sputtering method, the above atomic ratio is not limited to the atomic ratio of the formed metal oxide film and may be the atomic ratio of a sputtering target used for forming the metal oxide film.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where light irradiation is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state; thus, the amount of change in threshold voltage in the PBTS test is one important item to be focused on as an indicator of the reliability of the transistor.

With use of a metal oxide that does not contain gallium or has a low gallium content percentage in the semiconductor layer, the transistor can be highly reliable against positive bias application. That is, the amount of change in the threshold voltage of the transistor in the PBTS test can be small. Meanwhile, with use of a metal oxide that contains gallium, the gallium content percentage is preferably lower than the indium content percentage. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, at the interface between a metal oxide containing a large amount of gallium and the gate insulating layer, gallium is bonded to excess oxygen in the gate insulating layer, which probably generates trap sites of carriers (here, electrons) easily. This might cause the change in the threshold voltage when a positive potential is supplied to a gate and carriers are trapped at the interface between the semiconductor layer and the gate insulating layer.

More specifically, in the case where In—Ga—Zn oxide is used for the semiconductor layer, a metal oxide in which the atomic ratio of indium is higher than the atomic ratio of gallium can be used for the semiconductor layer. It is further preferable to use a metal oxide in which the atomic ratio of zinc is higher than the atomic ratio of gallium. In other words, a metal oxide in which the atomic ratio of metal elements satisfies In>Ga and Zn>Ga is preferably used for the semiconductor layer.

For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof may be used for the semiconductor layer of the OS transistor.

The semiconductor layer of the OS transistor is preferably formed using a metal oxide having the following compositions: the proportion of the number of gallium atoms in the number of atoms of the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content percentage in the semiconductor layer enables the transistor to be highly resistant to the PBTS test. Note that oxygen vacancy (Vo) is less likely to be generated in the metal oxide when the metal oxide contains gallium.

A metal oxide not containing gallium may be used for the semiconductor layer of the OS transistor. For example, In—Zn oxide can be used for the semiconductor layer. In this case, when the ratio of the number of indium atoms in the number of atoms of the metal elements contained in the metal oxide is increased, the field-effect mobility of the transistor can be increased. By contrast, when the ratio of the number of zinc atoms in the number of atoms of the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer. The use of a metal oxide not containing gallium can make a change in the threshold voltage particularly in the PBTS test extremely small.

For example, an oxide containing indium and zinc can be used for the semiconductor layer. In that case, for example, a metal oxide where the atomic ratio of metal elements is In:Zn=2:3, In:Zn=4:1, or the neighborhood thereof can be used.

Although the case of using gallium is described as a typical example, the same applies to the case where the element M is used instead of gallium. A metal oxide in which the atomic ratio of indium is higher than the atomic ratio of the element M is preferably used for the semiconductor layer. Furthermore, a metal oxide in which the atomic ratio of zinc is higher than the atomic ratio of the element M is preferably used.

The use of a metal oxide having a low content percentage of the element M for the semiconductor layer achieves the transistor that is highly reliable against positive bias application. With use of the transistor as a transistor that is required to have high reliability against positive bias application, a highly reliable semiconductor device can be achieved.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

For example, a stacked-layer structure of a first metal oxide layer having a composition of In:M:Zn=1:1:1 [atomic ratio] or in the neighborhood thereof and a second metal oxide layer having a composition of In:Zn=4:1 [atomic ratio] or in the neighborhood thereof and being provided over the first metal oxide layer may be used.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which achieves a highly reliable display device.

The higher the crystallinity of the metal oxide layer used as the semiconductor layer is, the lower the density of defect states in the semiconductor layer can be. By contrast, the use of a metal oxide layer having low crystallinity achieves a transistor through which a large amount of current can flow.

In the case where a metal oxide layer is formed by a sputtering method, the metal oxide layer with higher crystallinity can be formed as the substrate temperature (the stage temperature) in formation is increased. The metal oxide layer with higher crystallinity can be formed as the proportion of a flow rate of an oxygen gas to the whole gas (also referred to as oxygen flow rate ratio) used in film formation is increased.

The semiconductor layer of the OS transistor may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer may have different compositions.

In the case where an oxide semiconductor is used for the semiconductor layer 161, a material containing hydrogen is preferably used for the insulating layer 156 and the insulating layer 158. When the insulating layer containing hydrogen is in contact with the oxide semiconductor, the oxide semiconductor in a region in contact with the insulating layer becomes an n-type semiconductor and can function as a source region or a drain region. For example, a material containing silicon, nitrogen, and hydrogen may be used for the insulating layer. Specifically, silicon nitride containing hydrogen or silicon nitride oxide containing hydrogen may be used.

The thickness of each of the insulating layer 156 and the insulating layer 158 is preferably greater than or equal to 1 nm and less than or equal to 15 nm, further preferably greater than or equal to 2 nm and less than or equal to 10 nm, still further preferably greater than or equal to 3 nm and less than or equal to 7 nm, yet still further preferably greater than or equal to 3 nm and less than or equal to 5 nm. In the case where an oxide semiconductor is used for the semiconductor layer 161, the region of the semiconductor layer 161 that is in contact with the insulating layer 156 containing hydrogen and the region of the semiconductor layer 161 that is in contact with the insulating layer 158 containing hydrogen function as a source region and a drain region. The sizes of the source region and the drain region formed in the semiconductor layer 161 can be controlled by adjusting the thicknesses of the insulating layer 156 and the insulating layer 158.

The thickness of the insulating layer 157 is preferably greater than or equal to 1 nm and less than or equal to 50 nm, further preferably greater than or equal to 2 nm and less than or equal to 30 nm, still further preferably greater than or equal to 3 nm and less than or equal to 20 nm. The size of a channel formation region of the semiconductor layer 161 can be controlled by adjusting the thickness of the insulating layer 157.

The thicknesses of the insulating layer 156, the insulating layer 157, and the insulating layer 158 may be set as appropriate in accordance with the characteristics required for the transistor 10.

The insulating layer 156, the insulating layer 157, and the insulating layer 158 are preferably formed successively without exposure to the atmospheric environment. When the insulating layer 156, the insulating layer 157, and the insulating layer 158 are successively formed without exposure to the atmospheric environment, impurities or moisture in the atmospheric environment can be prevented from being attached to the interface between the insulating layer 156 and the insulating layer 157 and the vicinity thereof and the interface between the insulating layer 157 and the insulating layer 158 and the vicinity thereof.

In the case where an oxide semiconductor is used for the semiconductor layer 161, a conductive material that makes the oxide semiconductor an n-type semiconductor is preferably used for the conductive layer 155 in contact with the semiconductor layer 161 and the conductive layer 160 in contact with the semiconductor layer 161. For example, a conductive material containing nitrogen may be used. For example, a conductive material containing nitrogen and titanium or tantalum may be used. Another conductive material may be provided so as to overlap with the conductive material containing nitrogen.

Meanwhile, for the insulating layer 157, a material which includes oxygen and a reduced amount of hydrogen is preferably used. For example, a material containing silicon and oxygen may be used. Specifically, silicon oxide, silicon oxynitride, or the like may be used. Since hydrogen is an impurity element in an oxide semiconductor, when the semiconductor layer 161, which is an oxide semiconductor, and the insulating layer 157, which includes a reduced amount of hydrogen, are in contact with each other, the semiconductor layer 161 is less likely to become an n-type layer. Furthermore, when the semiconductor layer 161, which is an oxide semiconductor, and the insulating layer 157 containing oxygen are in contact with each other, oxygen vacancies in the semiconductor layer 161 are reduced and the transistor 10 has stable characteristics and improved reliability.

When an oxide semiconductor is used for the semiconductor layer 161, the insulating layer 157 preferably includes excess oxygen. In this specification and the like, excess oxygen refers to oxygen that is released by heating. In the case where a material containing excess oxygen is used for the insulating layer 157, a material through which oxygen is less likely to pass is preferably used for the insulating layer 156 and the insulating layer 158. Examples of the material through which oxygen is less likely to pass include a nitride of silicon and an oxide containing one or both of aluminum and hafnium. When the material through which oxygen is less likely to pass is used for the insulating layer 156 and the insulating layer 158, excess oxygen included in the insulating layer 157 is less likely to be released to a lower layer or an upper layer. Thus, a sufficient amount of oxygen can be supplied to the oxide semiconductor. For example, it is possible to use a structure in which an insulating layer containing silicon and oxygen (the insulating layer 157) is provided between two insulating layers containing silicon and nitrogen (the insulating layer 156 and the insulating layer 158).

When an oxide semiconductor is used for the semiconductor layer 161 and a material containing hydrogen is used for the insulating layer 156 and the insulating layer 158, the region of the semiconductor layer 161 that is in contact with the insulating layer 156 and the region of the semiconductor layer 161 that is in contact with the insulating layer 158 are supplied with hydrogen and become n-type regions. Thus, the region of the semiconductor layer 161 that is in contact with the conductive layer 155 and the region of the semiconductor layer 161 that is in contact with the insulating layer 156 function as one of a source (a source region) and a drain (a drain region). The region of the semiconductor layer 161 that is in contact with the conductive layer 160 and the region of the semiconductor layer 161 that is in contact with the insulating layer 158 function as the other of the source (the source region) and the drain (the drain region).

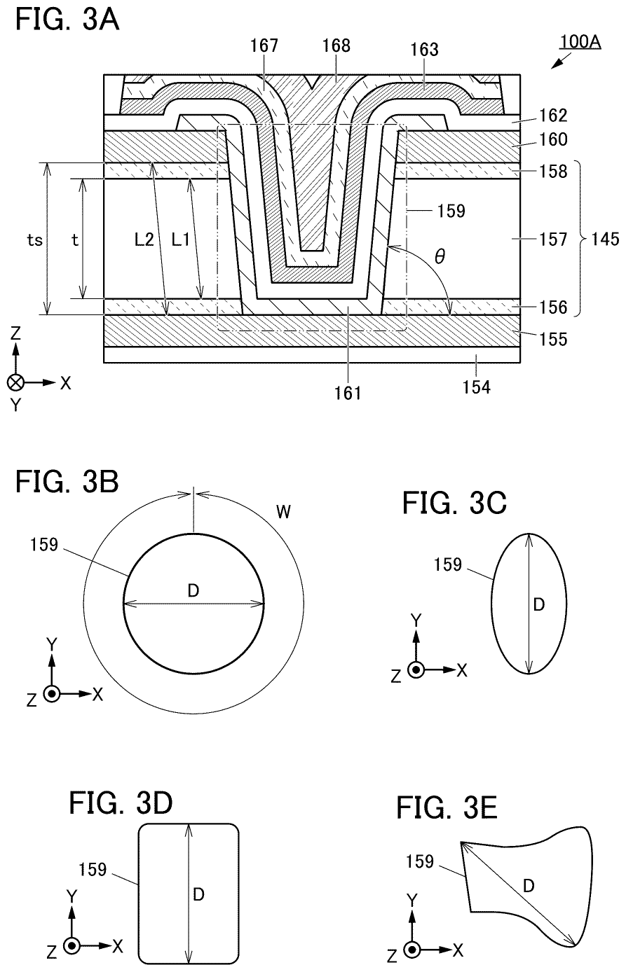

In that case, the length of the side surface of the insulating layer 157 seen from the X direction or the Y direction is the channel length L (channel length L1) (see FIG. 3A). Hence, the channel length L of the transistor 10 is determined in accordance with a thickness t of the insulating layer 157. FIG. 3A is an enlarged cross-sectional view of the transistor 10 illustrated in FIG. 1B.

A material that includes no hydrogen or an extremely small amount of hydrogen may be used for the insulating layer 156 and the insulating layer 158. For example, silicon nitride that includes an extremely small amount of hydrogen or silicon nitride oxide that includes an extremely small amount of hydrogen may be used. In that case, the region of the semiconductor layer 161 that is in contact with the insulating layer 156 and the region of the semiconductor layer 161 that is in contact with the insulating layer 158 are not become n-type regions. Thus, the region of the semiconductor layer 161 that is in contact with the conductive layer 155 functions as one of the source (the source region) and the drain (the drain region). The region of the semiconductor layer 161 that is in contact with the conductive layer 160 functions as the other of the source (the source region) and the drain (the drain region). The region of the semiconductor layer 161 that is in contact with the insulating layer 157 functions as the channel formation region.

In that case, the channel length L (channel length L2) is the sum of the lengths of side surfaces of the insulating layer 156, the insulating layer 157, and the insulating layer 158 seen from the X direction or the Y direction. Hence, the channel length L of the transistor 10 is determined in accordance with a thickness ts, which is the sum of the thicknesses of the insulating layer 156, the insulating layer 157, and the insulating layer 158.

The channel length L of the transistor 10 of one embodiment of the present invention is determined in accordance with the thickness of the insulating layer provided between the conductive layer 160 and the conductive layer 155. As a result, the transistor with a short channel length L can be formed with high accuracy. In addition, variations in characteristics among a plurality of transistors 10 are also reduced. Thus, the semiconductor device including the transistors 10 can operate stably and have high reliability. The reduced variations in characteristics increases the circuit design flexibility of the semiconductor device, thereby reducing the operation voltage. Thus, the power consumption of the semiconductor device can be reduced.

Although this embodiment shows the structure in which three insulating layers (the insulating layer 156, the insulating layer 157, and the insulating layer 158) are provided as the insulating layer 145 between the conductive layer 155 and the conductive layer 160, the number of insulating layers (the insulating layer 145) between the conductive layer 155 and the conductive layer 160 is not limited to three. The number of insulating layers between the conductive layer 155 and the conductive layer 160 may be one, two, or four or more.

Each of the insulating layer 156, the insulating layer 157, the insulating layer 158, and the conductive layer 160 may have a tapered side surface. A taper angle θ of the side surface of each of the insulating layer 156, the insulating layer 157, the insulating layer 158, and the conductive layer 160 (a taper angle θ of the side surface of the opening 159) may be greater than or equal to 45° and less than or equal to 90°, preferably greater than or equal to 50° and less than or equal to 75°. Note that the taper angle θ of the side surface of the layer (the insulating layer, the conductive layer, or the semiconductor layer) refers to the angle formed between the bottom surface and the side surface of the layer (see FIG. 3A). When the taper angle θ of the side surface of each of the insulating layer 156, the insulating layer 157, the insulating layer 158, and the conductive layer 160 is reduced, the coverage with the semiconductor layer 161, the insulating layer 162, the conductive layer 163, the insulating layer 167, and the conductive layer 168 formed in the opening 159 can be improved. Meanwhile, when the taper angle θ of the side surface of each of the insulating layer 156, the insulating layer 157, the insulating layer 158, and the conductive layer 160 is increased, the area occupied by the transistor 10 can be reduced.

Since the semiconductor layer 161 is provided in the opening 159, the length of the circumference of the opening 159 seen from the Z direction is the channel width W of the transistor 10 (see FIG. 3B). The length of the circumference is determined, for example, at the position of half (t/2) of the thickness t of the insulating layer 157 or at the position of half (ts/2) of the thickness ts of the insulating layer 145. Note that the length of the circumference of the opening 159 at an arbitrary position may be regarded as the channel width W as necessary. For example, the length of the circumference at the lowest portion of the opening 159 may be regarded as the channel width W, or the length of the circumference at the uppermost portion of the opening 159 may be regarded as the channel width W.

In the storage device of one embodiment of the present invention, the channel length L is preferably shorter than at least the channel width W. In one embodiment of the present invention, the channel length L is greater than or equal to 0.1 times and less than or equal to 0.99 times, preferably greater than or equal to 0.5 times and less than or equal to 0.8 times the channel width W.

Although the outline (the planar shape) of the opening 159 seen from the Z direction is circular in FIG. 3B, the outline is not limited to this. For example, the outline of the opening 159 seen from the Z direction may be elliptical (see FIG. 3C) or rectangular (see FIG. 3D). Note that FIG. 3D shows a rectangular shape having rounded corner portions. For another example, the outline of the opening 159 seen from the Z direction may have a shape including one or both of a straight portion and a curved portion (see FIG. 3E).

Note that the opening 159 preferably has a minute size. For example, a maximum width D of the opening 159 (the maximum diameter in the case where the opening 159 is circular) seen from the Z direction is preferably less than or equal to 60 nm, further preferably less than or equal to 50 nm, still further preferably less than or equal to 40 nm, yet still further preferably less than or equal to 30 nm. The maximum width D of the opening 159 seen from the Z direction may be less than or equal to 20 nm. Note that the minimum width of the opening 159 (the minimum diameter in the case where the opening 159 is circular) seen from the Z direction is preferably greater than or equal to 1 nm, further preferably greater than or equal to 5 nm. Such a minute opening 159 is preferably formed by a lithography method using short-wavelength light such as EUV (Extreme ultraviolet) light or a lithography method using an electron beam (electron beam lithography method).

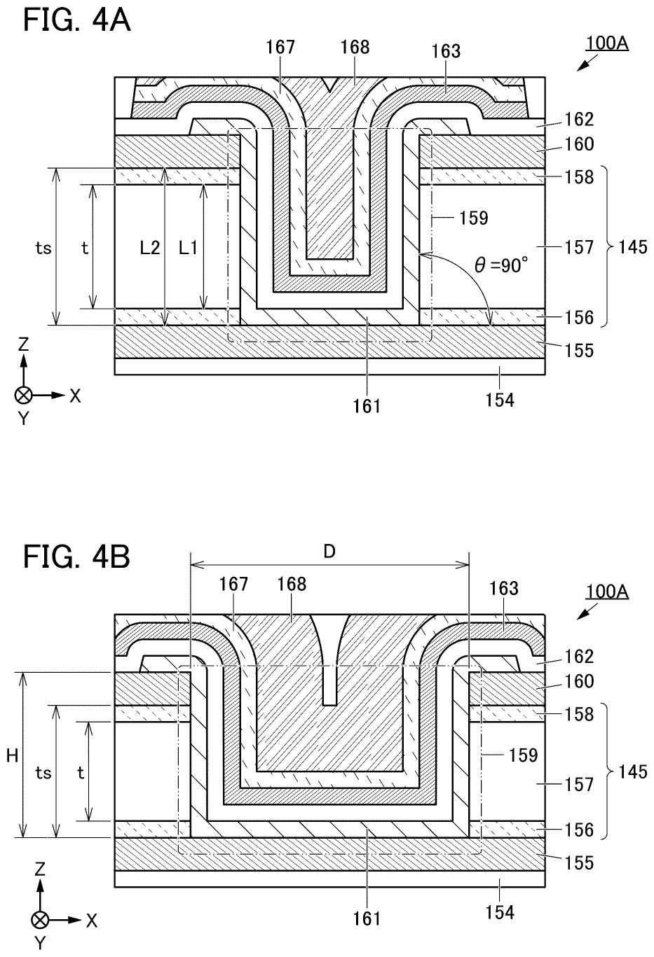

FIG. 4A and FIG. 4B are modification examples of FIG. 3A and correspond to an enlarged cross-sectional view of the transistor 10 illustrated in FIG. 1B.

As illustrated in FIG. 4A, the taper angle θ of the side surface of each of the insulating layer 156, the insulating layer 157, the insulating layer 158, and the conductive layer 160 (the taper angle θ of the side surface of the opening 159) may be 90°. In the case where the taper angle θ is 90°, the channel length L1 is equal to the thickness t. Furthermore, the channel length L2 is equal to the thickness ts.

As illustrated in FIG. 4B, a height H of the opening 159 (or the sum of the thicknesses of the insulating layer 156, the insulating layer 157, the insulating layer 158, and the conductive layer 160) may be smaller than the maximum width D of the opening 159. The height H smaller than the maximum width D can improve the coverage with the semiconductor layer 161, the insulating layer 162, the conductive layer 163, the insulating layer 167, and the conductive layer 168 that are formed in the opening 159. Note that the height H is preferably less than or equal to 0.8 times, further preferably less than or equal to 0.5 times the maximum width D.

### <Modification Example 1>

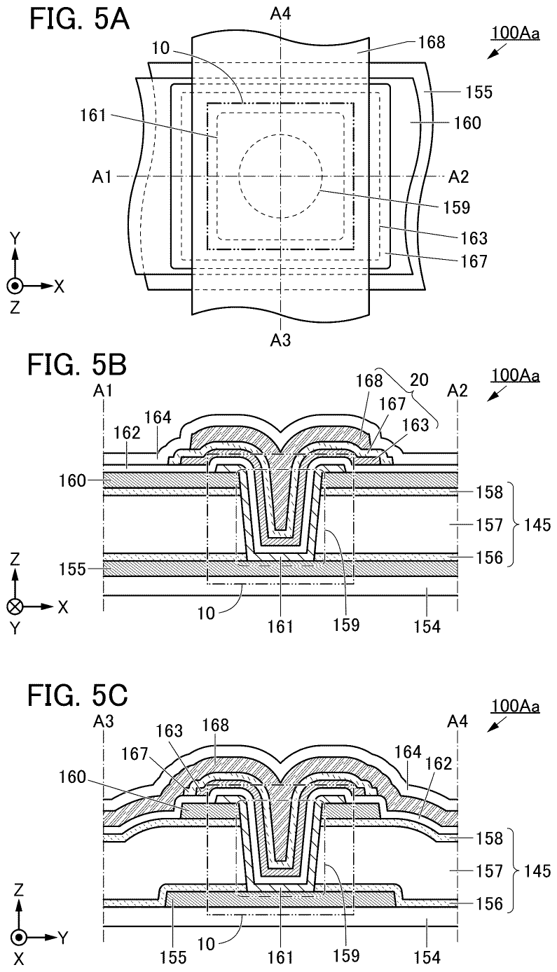

FIG. 5 illustrates a semiconductor device 100Aa, which is a modification example of the semiconductor device 100A. FIG. 5A is a plan view of the semiconductor device 100Aa. FIG. 5B is a cross-sectional view of a portion indicated by the dashed-dotted line A1-A2 in FIG. 5A, which is seen from the Y direction. FIG. 5C is a cross-sectional view of a portion indicated by the dashed-dotted line A3-A4 in FIG. 5A, which is seen from the X direction. Note that some components are omitted in the plan view in FIG. 5A for clarity of the drawing.

The semiconductor device 100Aa is different from the semiconductor device 100A (see FIG. 1B) in that the insulating layer 167 includes a region extending beyond the end portion of the conductive layer 163 in FIG. 5B. As in the semiconductor device 100Aa, the conductive layer 163 may be covered with the insulating layer 167. Such a structure can prevent a short circuit between the conductive layer 163 and the conductive layer 168 at the end portion of the conductive layer 163. Thus, the reliability of the semiconductor device 100Aa can be increased.

When a side surface of the capacitor element 20, which includes end portions of the conductive layer 163, the insulating layer 167, and the conductive layer 168, has a tapered shape, the coverage with the insulating layer 164 can be improved. When seen from the Z direction, the end portions of the conductive layer 163, the insulating layer 167, and the conductive layer 168 are not aligned with each other; thus, the end portions of the conductive layer 163, the insulating layer 167, and the conductive layer 168 are stair-stepped, which can improve the coverage with the insulating layer 164. Thus, the reliability of the semiconductor device 100Aa can be increased.

### <Modification Example 2>

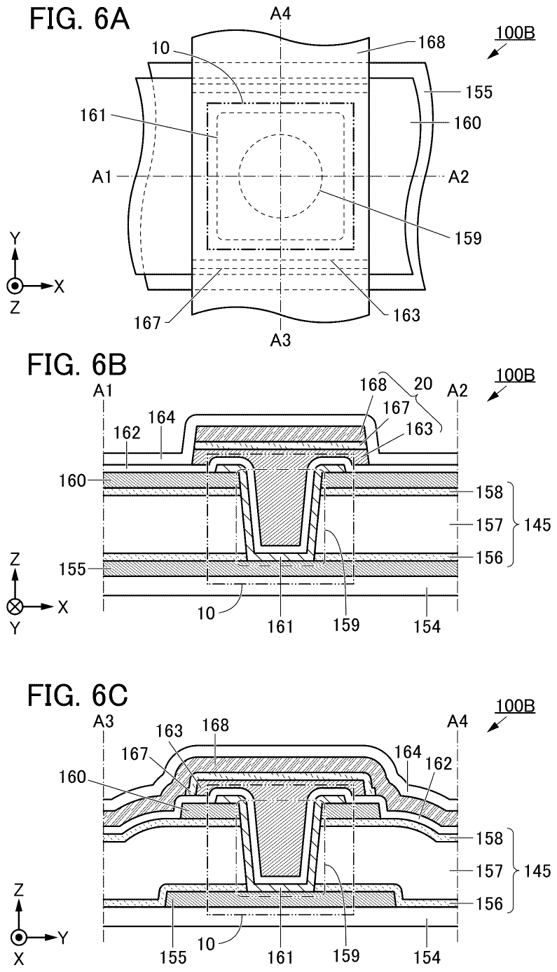

FIG. 6 illustrates a semiconductor device 100B, which is a modification example of the semiconductor device 100A. FIG. 6A is a plan view of the semiconductor device 100B. FIG. 6B is a cross-sectional view of a portion indicated by the dashed-dotted line A1-A2 in FIG. 6A, which is seen from the Y direction. FIG. 6C is a cross-sectional view of a portion indicated by the dashed-dotted line A3-A4 in FIG. 6A, which is seen from the X direction. Note that some components are omitted in the plan view in FIG. 6A for clarity of the drawing.

The semiconductor device 100B is different from the semiconductor device 100A in the structure of the capacitor element 20. The semiconductor device 100B has a structure in which in the plan view, the opening 159 is filled with part of the conductive layer 163 covering the opening 159 and the semiconductor layer 161. In addition, a top surface of the conductive layer 163 is planarized. Planarization of the top surface of the conductive layer 163 can be achieved by chemical mechanical polishing (CMP) treatment or the like. Specifically, a conductive film for forming the conductive layer 163 is formed to be rather thick over the insulating layer 162, and the surface unevenness of the conductive film is reduced by a CMP method. After that, a resist mask is formed by a lithography method and an etching step is performed with the resist mask used as a mask, whereby the conductive layer 163 with a planarized top surface can be formed. A minute pattern can be easily formed by reducing the surface unevenness of the conductive film, which reduces the area occupied by the semiconductor device 100B. In addition, the storage density (the number of memory cells per unit area) of a storage device using the semiconductor device 100B as a memory cell can be increased.

After that, the insulating layer 167 that is a ferroelectric can be formed over the flat surface of the conductive layer 163, that is, the insulating layer 167 can be formed by a sputtering method or the like without any concern for coverage. In addition, the thickness of the insulating layer 167 can be made uniform and easily controlled. Thus, the reliability of the semiconductor device 100B can be increased.

### <Modification Example 3>

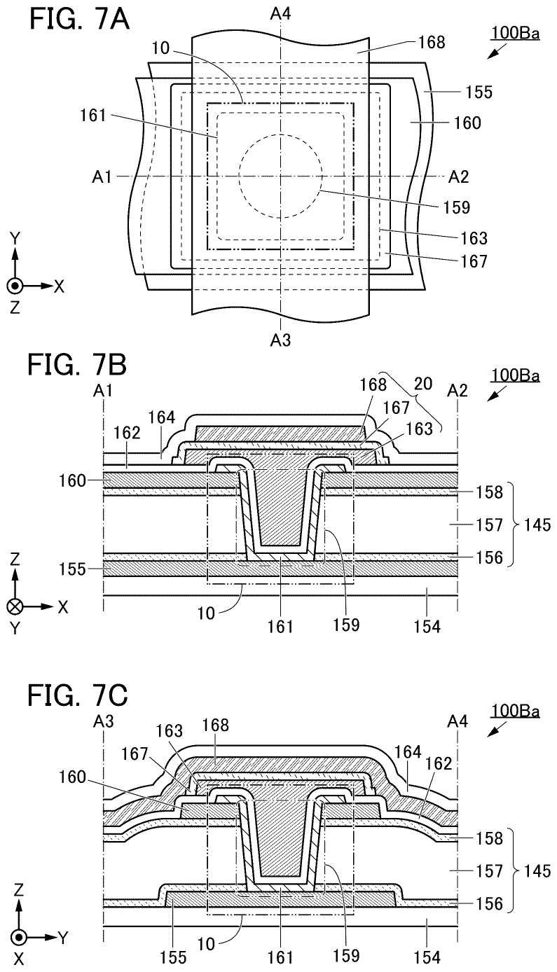

FIG. 7 illustrates a semiconductor device 100Ba, which is a modification example of the semiconductor device 100B. FIG. 7A is a plan view of the semiconductor device 100Ba. FIG. 7B is a cross-sectional view of a portion indicated by the dashed-dotted line A1-A2 in FIG. 7A, which is seen from the Y direction. FIG. 7C is a cross-sectional view of a portion indicated by the dashed-dotted line A3-A4 in FIG. 7A, which is seen from the X direction. Note that some components are omitted in the plan view in FIG. 7A for clarity of the drawing.

The semiconductor device 100Ba is different from the semiconductor device 100B in that the insulating layer 167 includes a region extending beyond the end portion of the conductive layer 163 in FIG. 7B. As in the semiconductor device 100Ba, the conductive layer 163 may be covered with the insulating layer 167. Such a structure can prevent a short circuit between the conductive layer 163 and the conductive layer 168 at the end portion of the conductive layer 163. When the side surface of the capacitor element 20, which includes the end portions of the conductive layer 163, the insulating layer 167, and the conductive layer 168, has a tapered shape or a stair-stepped shape as in the semiconductor device 100Aa, the coverage with the insulating layer 164 can be improved. Thus, the reliability of the semiconductor device 100Ba can be increased.

### <Modification Example 4>

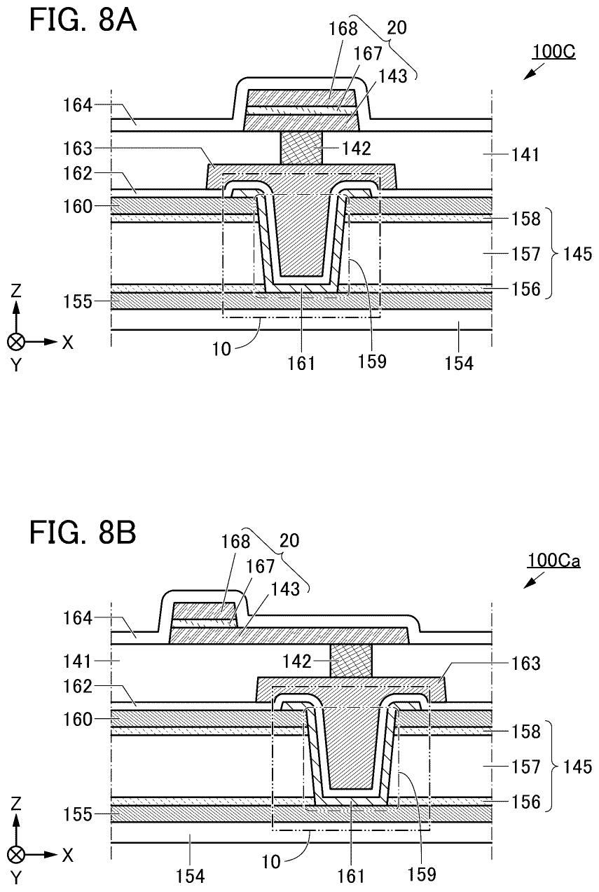

FIG. 8A illustrates a semiconductor device 100C, which is a modification example of the semiconductor device 100B. FIG. 8A is a cross-sectional view of the semiconductor device 100C, which is seen from the Y direction. FIG. 8B illustrates a semiconductor device 100Ca, which is a modification example of the semiconductor device 100C. FIG. 8B is a cross-sectional view of the semiconductor device 100Ca, which is seen from the Y direction.

The semiconductor device 100C includes an insulating layer 141 over the insulating layer 162 and the conductive layer 163. A conductive layer 142 is provided over the conductive layer 163. The conductive layer 142 is formed to be embedded in the insulating layer 141 and is electrically connected to the conductive layer 163.

A conductive layer 143 is provided over the insulating layer 141 and the conductive layer 142, the insulating layer 167 is provided over the conductive layer 143, and the conductive layer 168 is provided over the insulating layer 167. A region where the conductive layer 143 and the conductive layer 168 overlap with each other with the insulating layer 167 therebetween functions as the capacitor element 20. The conductive layer 168 functions as one electrode of the capacitor element 20, and the conductive layer 143 functions as the other electrode of the capacitor element 20. The conductive layer 143 and the conductive layer 163 are electrically connected to each other via the conductive layer 142.

The transistor 10 and the capacitor element 20 can be designed with a high degree of freedom because they are provided with the insulating layer and the conductive layer therebetween. The insulating layer 141 and the conductive layer 142 preferably have flat top surfaces. As in the semiconductor device 100Ca illustrated in FIG. 8B, a structure in which the capacitor element 20 does not overlap with the transistor 10 may be employed depending on the purpose or the like.

### <Modification Example 5>

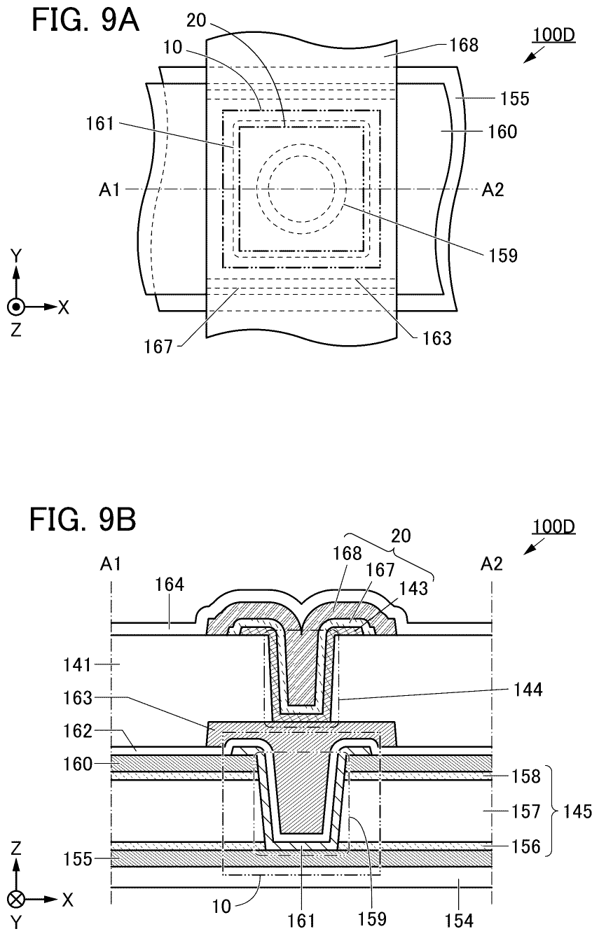

FIG. 9A illustrates a semiconductor device 100D, which is a modification example of the semiconductor device 100B. FIG. 9A is a plan view of the semiconductor device 100D. FIG. 9B is a cross-sectional view of a portion indicated by the dashed-dotted line A1-A2 in FIG. 9A, which is seen from the Y direction. Note that some components are omitted in the plan view in FIG. 9A for clarity of the drawing.

The semiconductor device 100D includes the insulating layer 141 over the insulating layer 162 and the conductive layer 163. An opening 144 is provided in part of the insulating layer 141, which is in a region overlapping with part of the conductive layer 163. The semiconductor device 100D includes the conductive layer 143 covering the opening 144. The conductive layer 143 includes a region that overlaps with the conductive layer 163 and is electrically connected to the conductive layer 163 in a bottom portion of the opening 144. The conductive layer 143 includes a region overlapping with a side surface of the opening 144. That is, the conductive layer 143 includes a region in contact with a side surface of the insulating layer 141.

The semiconductor device 100D also includes the insulating layer 167 covering the opening 144. The insulating layer 167 includes a region that overlaps with the conductive layer 163 with the conductive layer 143 therebetween in the bottom portion of the opening 144. The insulating layer 167 also includes a region that overlaps with the side surface of the insulating layer 141 with the conductive layer 143 therebetween.

The semiconductor device 100D includes the conductive layer 168 covering the opening 144 in the plan view. The conductive layer 168 includes a region that overlaps with the conductive layer 163 with the insulating layer 167 and the conductive layer 143 therebetween in the bottom portion of the opening 144. The conductive layer 168 also includes a region that overlaps with the side surface of the insulating layer 141 with the insulating layer 167 and the conductive layer 143 therebetween.

A region where the conductive layer 168 and the conductive layer 143 overlap with each other with the insulating layer 167 therebetween functions as the capacitor element 20. Since the capacitor element 20 of the semiconductor device 100D is provided in the opening 144, the capacitance value of the capacitor element 20 can be increased without increase in occupation area seen from the Z direction.

### <Modification Example 6>

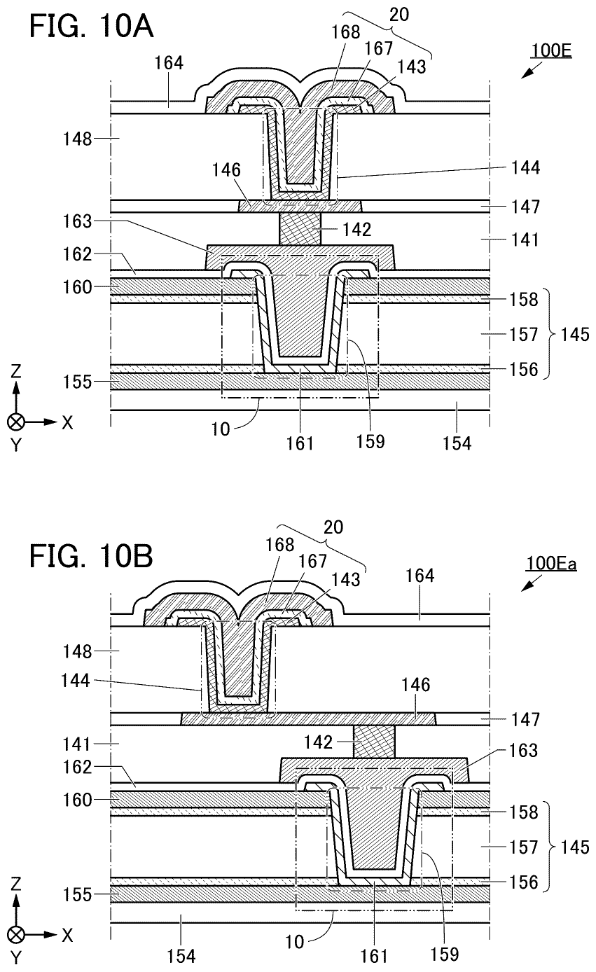

FIG. 10A illustrates a semiconductor device 100E, which is a modification example of the semiconductor device 100D. FIG. 10A is a cross-sectional view of the semiconductor device 100E, which is seen from the Y direction. FIG. 8B illustrates a semiconductor device 100Ea, which is a modification example of the semiconductor device 100E. FIG. 10B is a cross-sectional view of the semiconductor device 100Ea, which is seen from the Y direction.

The semiconductor device 100E includes the insulating layer 141 over the insulating layer 162 and the conductive layer 163. The conductive layer 142 is provided over the conductive layer 163. The conductive layer 142 is formed to be embedded in the insulating layer 141 and is electrically connected to the conductive layer 163.

An insulating layer 147 is provided over the insulating layer 141, and a conductive layer 146 is provided over the conductive layer 142. The conductive layer 146 is formed to be embedded in the insulating layer 147 and is electrically connected to the conductive layer 142.

The semiconductor device 100E includes an insulating layer 148 over the insulating layer 147 and the conductive layer 146. The opening 144 is provided in part of the insulating layer 148, which is in a region overlapping with part of the conductive layer 146. The semiconductor device 100E includes the conductive layer 143 covering the opening 144 when seen from the Z direction. The conductive layer 143 includes a region that overlaps with the conductive layer 146 and is electrically connected to the conductive layer 146 in the bottom portion of the opening 144. The conductive layer 143 includes a region overlapping with the side surface of the opening 144. That is, the conductive layer 143 includes a region in contact with a side surface of the insulating layer 148.

The semiconductor device 100E includes the insulating layer 167 covering the opening 144 when seen from the Z direction. The insulating layer 167 includes a region that overlaps with the conductive layer 146 with the conductive layer 143 therebetween in the bottom portion of the opening 144. The insulating layer 167 also includes a region that overlaps with the side surface of the insulating layer 148 with the conductive layer 143 therebetween.

The semiconductor device 100E includes the conductive layer 168 covering the opening 144 when seen from the Z direction. The conductive layer 168 includes a region that overlaps with the conductive layer 146 with the insulating layer 167 and the conductive layer 143 therebetween in the bottom portion of the opening 144. The conductive layer 168 also includes a region that overlaps with the side surface of the insulating layer 148 with the insulating layer 167 and the conductive layer 143 therebetween.

Also in the semiconductor device 100E, a region where the conductive layer 168 and the conductive layer 143 overlap with each other with the insulating layer 167 therebetween functions as the capacitor element 20. The conductive layer 168 functions as one electrode of the capacitor element 20, and the conductive layer 143 functions as the other electrode of the capacitor element 20. The conductive layer 143 and the conductive layer 163 are electrically connected to each other via the conductive layer 146 and the conductive layer 142. Since the capacitor element 20 of the semiconductor device 100E is provided in the opening 144, the capacitance value of the capacitor element 20 can be increased without increase in occupation area seen from the Z direction.

The transistor 10 and the capacitor element 20 can be designed with a high degree of freedom because they are provided with the insulating layer and the conductive layer therebetween. The insulating layer 147 and the conductive layer 146 preferably have flat top surfaces. As in the semiconductor device 100Ca illustrated in FIG. 10B, a structure in which the capacitor element 20 does not overlap with the transistor 10 may be employed depending on the purpose or the like.

### <Modification Example 7>

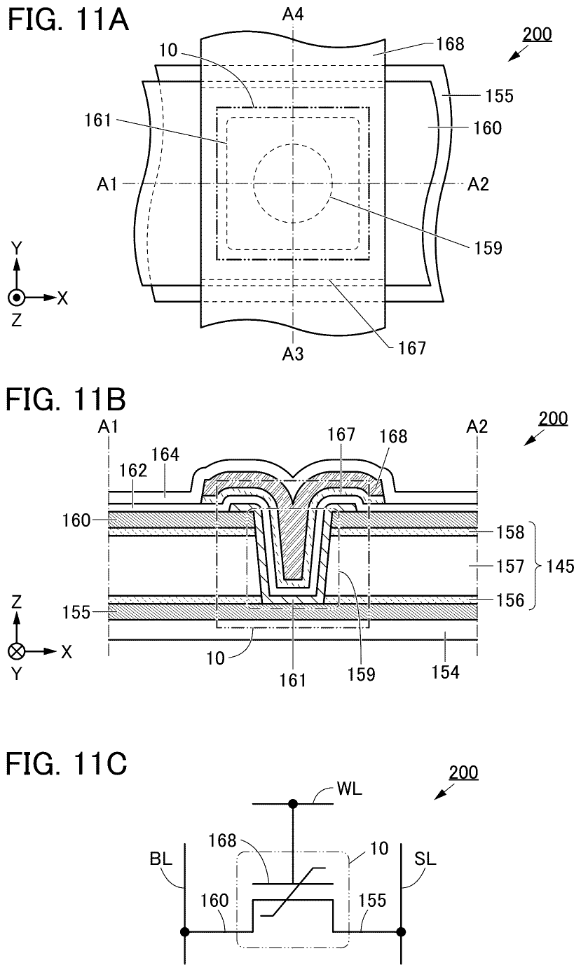

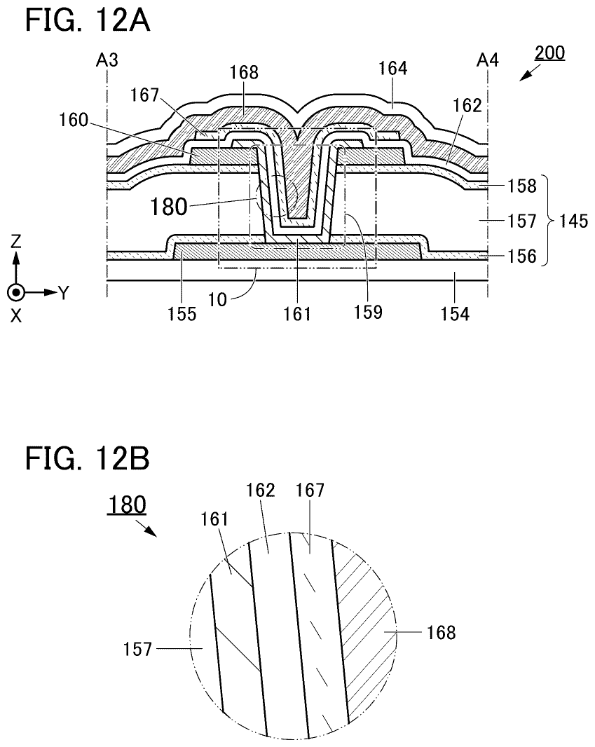

FIG. 11A illustrates a semiconductor device 200, which is a modification example of the semiconductor device 100A. FIG. 11A is a plan view of the semiconductor device 200. FIG. 11B is a cross-sectional view of a portion indicated by the dashed-dotted line A1-A2 in FIG. 11A, which is seen from the Y direction. Note that some components are omitted in the plan view in FIG. 11A for clarity of the drawing. FIG. 11C illustrates an equivalent circuit diagram of the semiconductor device 200. FIG. 12A is a cross-sectional view of a portion indicated by the dashed-dotted line A3-A4 in FIG. 11A, which is seen from the X direction. FIG. 12B is an enlarged view of a portion 180 illustrated in FIG. 12A.

The structure of the semiconductor device 200 is similar to the structure in which the conductive layer 163 is removed from the semiconductor device 100A. In other words, the semiconductor device 200, not being provided with the conductive layer 163, has a structure in which the capacitor element 20 is removed from the semiconductor device 100A. Since the capacitor element 20 is not formed, a semiconductor device with high productivity can be achieved.

In the semiconductor device 200, the insulating layer 167 functions as a gate insulating layer of the transistor 10. In the case where a ferroelectric is used for the insulating layer 167, unintentional current (leakage current) is likely to flow between the conductive layer 168 and the semiconductor layer 161. In order to prevent increase in leakage current, a paraelectric is preferably provided as the insulating layer 162 between the semiconductor layer 161 and the insulating layer 167.

### <<Operation Example of Semiconductor Device 100A>>

Next, an operation example of the semiconductor device 100A is described. As described above, the semiconductor device 100A of one embodiment of the present invention functions as a memory cell.

### [Hysteresis Characteristics of Ferroelectric]

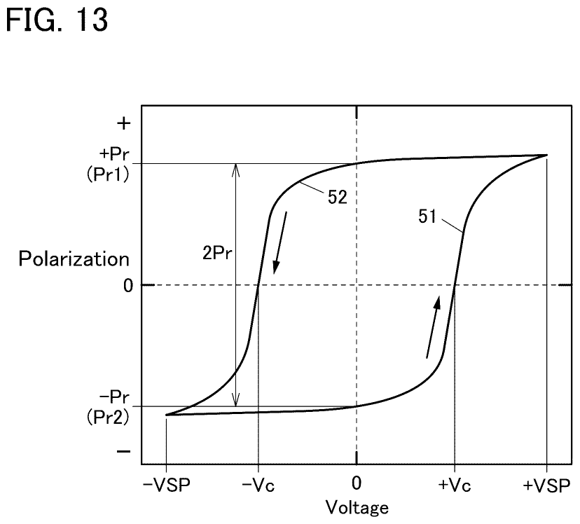

A ferroelectric has hysteresis characteristics. FIG. 13 is a graph showing an example of hysteresis characteristics of the ferroelectric. The hysteresis characteristics can be measured using a capacitor element including a ferroelectric (a ferroelectric capacitor). In FIG. 13, the horizontal axis represents voltage (electric field) applied to the ferroelectric. The voltage is a potential difference between one electrode and the other electrode of the ferroelectric capacitor. Note that the electric field strength can be obtained by dividing the potential difference by the thickness of the ferroelectric.

In FIG. 13, the vertical axis represents polarization of the ferroelectric. Positive polarization indicates that positive charge in the ferroelectric is biased toward one electrode side of the capacitor element and negative charge is biased toward the other electrode side of the capacitor element. By contrast, negative polarization indicates that negative charge in the ferroelectric is biased toward one electrode side of the capacitor element and positive charge is biased toward the other electrode side of the capacitor element.

The polarization represented by the vertical axis of the graph in FIG. 13 may be positive when negative charge is biased toward one electrode side of the capacitor element and positive charge is biased toward the other electrode side of the capacitor element, and may be negative when positive charge is biased toward one electrode side of the capacitor element and negative charge is biased toward the other electrode side of the capacitor element.

As shown in FIG. 13, the hysteresis characteristics of the ferroelectric can be represented by a curve 51 and a curve 52. Voltages at intersection points of the curve 51 and the curve 52 are referred to as a saturation polarization voltage +VSP (also referred to as “+VSP”) and a saturation polarization voltage −VSP (also referred to as “−VSP”). It can be said that +VSP and −VSP have different polarities.

When a voltage lower than or equal to −VSP is applied to the ferroelectric and then the voltage applied to the ferroelectric increases, the polarization of the ferroelectric increases along the curve 51. Meanwhile, when a voltage higher than or equal to +VSP is applied to the ferroelectric and then the voltage applied to the ferroelectric decreases, the polarization of the ferroelectric decreases along the curve 52. Note that in some cases, +VSP is referred to as a “positive saturation polarization voltage” or a “first saturation polarization voltage”, and −VSP is referred to as a “negative saturation polarization voltage” or a “second saturation polarization voltage”. The absolute value of the first saturation polarization voltage may be the same as or different from the absolute value of the second saturation polarization voltage.

The voltage at the time when the polarization of the ferroelectric changes along the curve 51 to reach 0 is referred to as a coercive voltage +Vc. The voltage at the time when the polarization of the ferroelectric changes along the curve 52 to reach 0 is referred to as a coercive voltage −Vc. The value of +Vc and the value of −Vc are each a value between +VSP and −VSP. In some cases, +Vc is referred to as a “positive coercive voltage” or a “first coercive voltage”, and −Vc is referred to as a “negative coercive voltage” or a “second coercive voltage”. The absolute value of the first coercive voltage may be the same as or different from the absolute value of the second coercive voltage.

When no voltage is applied to the ferroelectric (when the voltage is 0 V), the maximum value of polarization and the minimum value of polarization are referred to as “remanent polarization +Pr” or “remanent polarization Pr1” and “remanent polarization −Pr” or “remanent polarization Pr2”, respectively. The difference between the absolute values of the remanent polarization +Pr and the remanent polarization −Pr is referred to as “remanent polarization 2Pr”. A larger remanent polarization 2Pr increases the range of a change in the capacitance value of the ferroelectric capacitor due to polarization reversal. The remanent polarization 2Pr is preferably as large as possible.

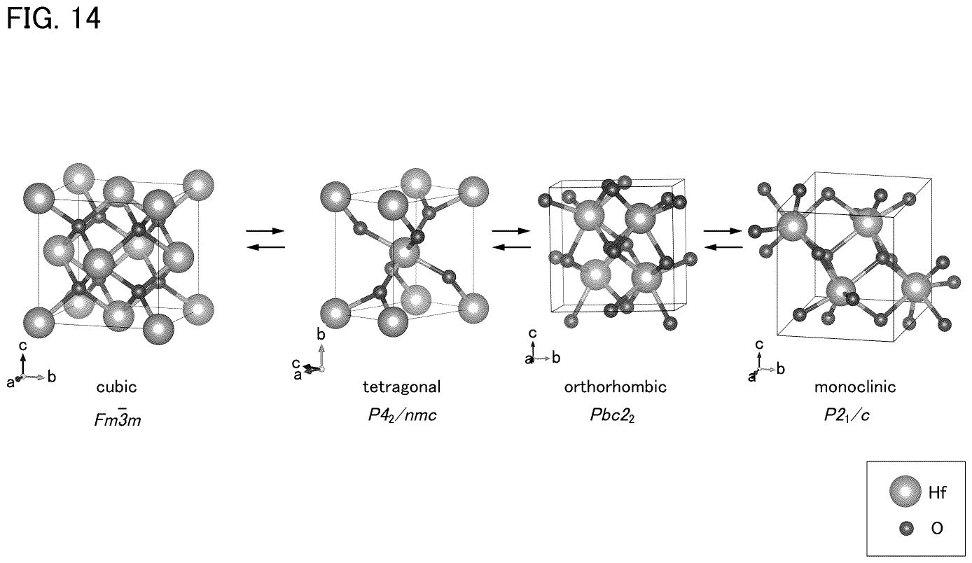

Crystal structures of hafnium oxide, which functions as a dielectric, are described here with reference to FIG. 14. FIG. 14 is a model diagram illustrating crystal structures of hafnium oxide. Hafnium oxide is known to take on various crystal structures and, for example, can take on crystal structures illustrated in FIG. 14 such as cubic (space group: Fm-3m), tetragonal (space group: P4₂/nmc), orthorhombic (space group: Pbc2₂), and monoclinic (space group: P2₁/c) crystal structures. As illustrated in FIG. 14, phase transition can occur between the above-described crystal structures. For example, the crystal structure of hafnium oxide can be changed from a crystal structure mainly based on a monoclinic system to a crystal structure mainly based on an orthorhombic system when the hafnium oxide is doped with zirconium to form a composite material.

In the case where hafnium oxide and zirconium oxide are alternately deposited by an ALD method or the like so as to achieve a composition ratio of hafnium oxide to zirconium oxide that is approximately 1:1 as the above-described composite material, the composite material has an orthorhombic crystal structure. Alternatively, the composite material has an amorphous structure. Then, the application of heat treatment or the like to the composite material can change the crystal structure from the amorphous structure to an orthorhombic crystal structure. Note that in some cases, the orthorhombic crystal structure can change to a monoclinic crystal structure. To make the above-described composite material have ferroelectricity, an orthorhombic crystal structure is preferred to a monoclinic crystal structure.

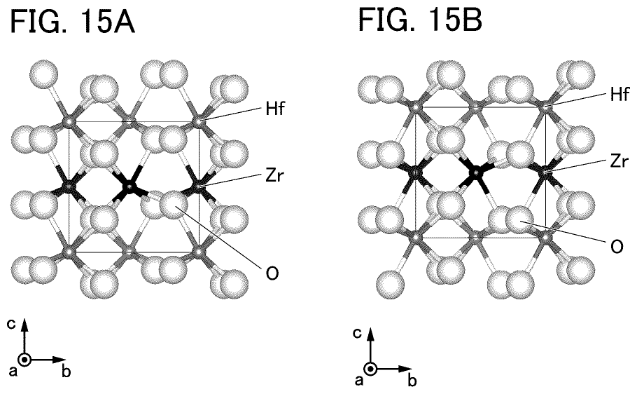

Here, a model of an orthorhombic crystal structure of HfZrOₓ is described with reference to FIG. 15A and FIG. 15B.

FIG. 15A and FIG. 15B are each a model diagram of the crystal structure of HfZrOₓ, which is here Hf_{0.5}Zr_{0.5}O₂. In FIG. 15A and FIG. 15B, the directions of the a-axis, the b-axis, and the c-axis are also indicated. FIG. 15A and FIG. 15B are each a model in which the arrangement of atoms is optimized by first-principles calculation on the orthorhombic structure (Pca2₁) of HfO₂.

In FIG. 15A and FIG. 15B, hafnium and zirconium are bonded to each other with oxygen positioned therebetween. This can be formed by alternately depositing hafnium and zirconium by an ALD method.

HfZrOₓ with an orthorhombic structure can have both the atomic arrangement shown in FIG. 15A and the atomic arrangement illustrated in FIG. 15B. Accordingly, when part of oxygen atoms in HfZrOₓ is displaced by the electric field applied from the outside, the polarization is generated inside. Here, part of oxygen atoms is displaced in the c-axis direction, and the polarization is also generated in the c-axis direction. A change in the direction or intensity of the electric field allows part of oxygen atoms in HfZrOₓ to be moved, resulting in a change of signs of the polarization generated inside.

For example, in the remanent polarization −Pr, atoms in HfZrOₓ are placed as illustrated in FIG. 15A. In the remanent polarization +Pr, atoms in HfZrOₓ are placed as illustrated in FIG. 15B.

### [Relation Between Polarization of Ferroelectric and Id-Vg Characteristics]

Next, the relation between the polarization of the ferroelectric included in the capacitor element 20 and the Id-Vg characteristics of the transistor 10 is described below.

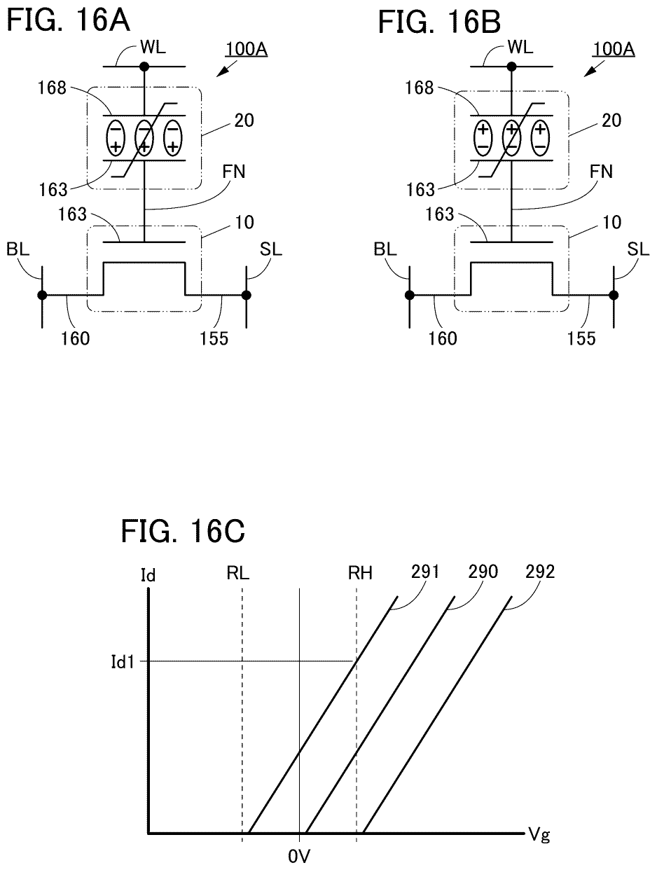

FIG. 16A and FIG. 16B are equivalent circuit diagrams of the semiconductor device 100A including the transistor 10 and the capacitor element 20 that is a ferroelectric capacitor. FIG. 16A and FIG. 16B schematically illustrate the polarization of the insulating layer 167 (see FIG. 1B), which is a ferroelectric layer included in the capacitor element 20.

FIG. 16C is a diagram showing the Id-Vg characteristics of the transistor 10 at the time when the voltage between the source and the drain (also referred to as a “drain voltage” or “Vd”) is constant. In FIG. 16C, the horizontal axis represents voltage between the source and the gate (also referred to as a “gate voltage” or “Vg”), and the vertical axis represents current flowing between the source and the drain (also referred to as a “drain current” or “Id”).

In FIG. 16C, characteristics 290 show the Id-Vg characteristics of the transistor 10 at the time when polarization is not caused in the insulating layer 167 included in the capacitor element 20.

In FIG. 16C, characteristics 291 show the Id-Vg characteristics at the time when the polarization of the insulating layer 167 is the remanent polarization Pr1. FIG. 16A is a schematic diagram showing the polarization of the insulating layer 167 included in the capacitor element 20 in the characteristics 291.

Since the remanent polarization Pr1 is positive polarization, a positive voltage is generated at a node FN. Thus, the Id-Vg characteristics of the characteristics 290 shift in the negative direction of Vg to be the characteristics 291. That is, the threshold voltage of the transistor 10 shifts in the negative direction of Vg.

In FIG. 16C, characteristics 292 show the Id-Vg characteristics at the time when the polarization of the insulating layer 167 is the remanent polarization Pr2. FIG. 16B is a schematic diagram showing the polarization of the insulating layer 167 included in the capacitor element 20 in the characteristics 292.

Since the remanent polarization Pr2 is negative polarization, a negative voltage is generated at the node FN. Thus, the Id-Vg characteristics of the characteristics 290 shift in the positive direction of Vg to be the characteristics 292. That is, the threshold voltage of the transistor 10 shifts in the positive direction of Vg.

As illustrated in FIG. 16A to FIG. 16C, the Id-Vg characteristics of the transistor 10 can be changed in accordance with the polarization of the insulating layer 167, which is a ferroelectric layer. In other words, by controlling the polarization of the insulating layer 167, the threshold voltage of the transistor 10 can be controlled. Thus, the semiconductor device 100A including the transistor 10 and the capacitor element 20 can function as a memory cell that can retain binary data.

For example, in the case where binary data of data “0” or “1” is written to the semiconductor device 100A functioning as a memory cell, the polarization of the insulating layer 167 is the remanent polarization Pr1 when data “1” is written, and the polarization of the insulating layer 167 is the remanent polarization Pr2 when data “0” is written. The Id-Vg characteristics of the semiconductor device 100A to which data “1” has been written become the characteristics 291. The Id-Vg characteristics of the semiconductor device 100A to which data “O” has been written become the characteristics 292.

Next, erasing, writing, retaining, and reading operations of the semiconductor device 100A will be described.

### <Erasing Operation>

Before data is written to the semiconductor device 100A functioning as a memory cell, data needs to be erased. In this embodiment, operation of writing data “0” to the semiconductor device 100A is performed as erasing operation. That is, the polarization of the insulating layer 167 is set to the remanent polarization Pr2.

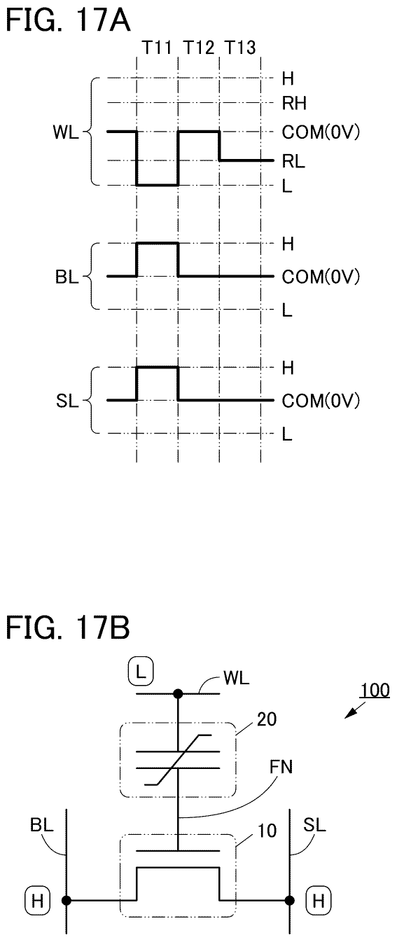

FIG. 17A is a timing chart for describing the erasing operation. FIG. 17B is a circuit diagram illustrating a state of the semiconductor device 100A in Period T11. Note that in the circuit diagram and the like, for easy understanding of the potential of a wiring or the like, a symbol showing the potential of the wiring is sometimes written adjacent to the wiring or the like. Furthermore, a symbol showing the potential of a wiring or the like whose potential has changed is sometimes denoted as an enclosed symbol.

In Period T11, a potential L is supplied to the wiring WL, and a potential H is supplied to the wiring BL and the wiring SL.

Note that a gate capacitance of the transistor 10 and the capacitor element 20 are connected in series between the wiring WL and the wiring BL and between the wiring WL and the wiring SL. A voltage applied to the capacitor element 20 is determined by the ratio of the gate capacitance of the transistor 10 and the capacitance of the capacitor element 20. In this embodiment, the ratio of the gate capacitance of the transistor 10 and the capacitance of the capacitor element 20 is 1:1. Accordingly, the potential difference between the potential H and the potential L is set to twice or more VSP. In order to change the polarization of the insulating layer 167 to the remanent polarization Pr2, the potential H is supplied to the wiring BL and the wiring SL, and the potential L is supplied to the wiring WL. The potential H is a potential higher than the potential L.

For example, in the case where a potential COM is a reference potential (0 V), the potential His higher than the potential COM and is different from the potential COM by +VSP. Similarly, the potential L is lower than the potential COM and is different from the potential COM by −VSP.

Under the above conditions, the potential L is supplied to the wiring WL and the potential H is supplied to the wiring BL and the wiring SL, whereby −VSP is applied to the capacitor element 20. Next, in Period T12, 0 V is supplied to the wiring WL, the wiring BL, and the wiring SL. That is, the wiring WL, the wiring BL, and the wiring SL are made to have the same potential.

In Period T12, the polarization of the insulating layer 167 becomes the remanent polarization Pr2 (see FIG. 13). Since the remanent polarization Pr2 is negative polarization as described above, a negative voltage is generated at the node FN. Thus, the Id-Vg characteristics of the characteristics 290 shift in the positive direction of Vg to be the characteristics 292. That is, the threshold voltage of the transistor 10 shifts in the positive direction of Vg (see FIG. 16C).

In Period T13, a potential RL is supplied to the wiring WL. The potential RL will be described in detail in the description of the retaining operation. Note that Period T12 may be omitted and Period T11 may be followed by Period T13. A negative voltage is generated at the node FN through Period T11 even when Period T12 is omitted.

### <Writing Operation>

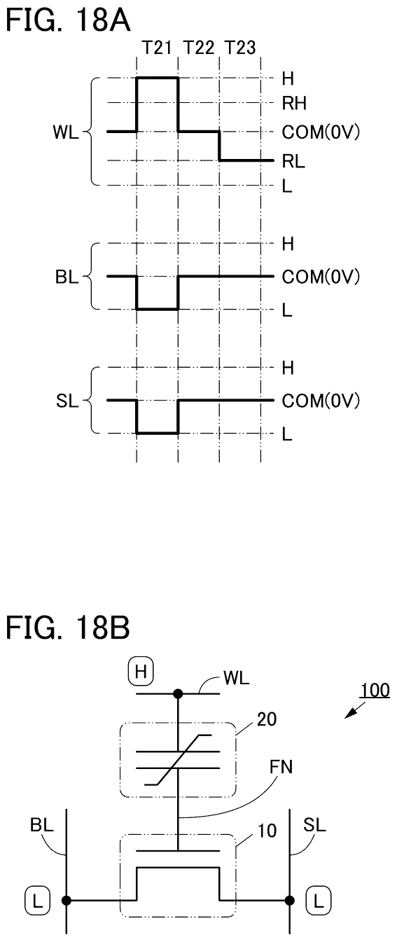

Next, operation of writing data “1” to the semiconductor device 100A functioning as a memory cell will be described. FIG. 18A is a timing chart for describing the writing operation. FIG. 18B is a circuit diagram illustrating a state of the semiconductor device 100 in Period T22.

After the erasing operation is performed in Period T11, the potential H is supplied to the wiring WL and the potential L is supplied to the wiring BL and the wiring SL in Period T21. Thus, +VSP is applied to the capacitor element 20, and the polarization of the insulating layer 167 changes along the curve 51 (see FIG. 13). Then, in Period T22, 0 V is supplied to the wiring WL, the wiring BL, and the wiring SL. That is, the wiring WL, the wiring BL, and the wiring SL are made to have the same potential.

In Period T22, the polarization of the insulating layer 167 becomes the remanent polarization Pr1 (see FIG. 13). Since the remanent polarization Pr1 is positive polarization as described above, a positive voltage is generated at the node FN. Thus, the Id-Vg characteristics of the characteristics 290 shift in the negative direction of Vg to be the characteristics 291. That is, the threshold voltage of the transistor 10 shifts in the negative direction of Vg (see FIG. 16C).

In this manner, the data “1” can be written to the semiconductor device 100A. Since the capacitor element 20 is a ferroelectric capacitor, polarization of the insulating layer 167, which is a ferroelectric, is maintained even when power supply to the semiconductor device 100A stops. Thus, data written to the semiconductor device 100A is maintained even when power supply to the semiconductor device 100A stops. Accordingly, the semiconductor device 100A functions as a nonvolatile memory cell.

The operation of writing data “0” to the semiconductor device 100A is the same as the above-described erasing operation. Accordingly, there is no need to perform the operation of writing data “0” after the erasing operation.

### <Retaining Operation>

After data is written to the semiconductor device 100A, the potential RL is supplied to the wiring WL in Period T23. The potential RL is a potential at which the transistor 10 is turned off even when the Id-Vg characteristics of the transistor 10 are the characteristics 291 (see FIG. 16C). Thus, the potential RL is preferably set to a potential lower than the threshold voltage of the characteristics 291. Moreover, in order to hardly cause a change in polarization of the insulating layer 167, the potential RL is set to a voltage with which a voltage applied to the capacitor element 20 is higher than or equal to the coercive voltage −Vc.

After the writing operation, the potential of the wiring WL is preferably the potential RL until the reading operation is performed. When the potential of the wiring WL remains as the potential RL, the transistor 10 is surely brought into an off state; thus, power consumption of the semiconductor device 100A is reduced. Moreover, in the case where the semiconductor devices 100A are arranged in a matrix to form a memory cell array, interference in the reading operation of another memory cell (semiconductor device 100A) can be prevented. Consequently, the memory cell array can have higher reliability.

Note that Period T22 may be omitted and Period T23 may be followed by Period T21.

### <Reading Operation>

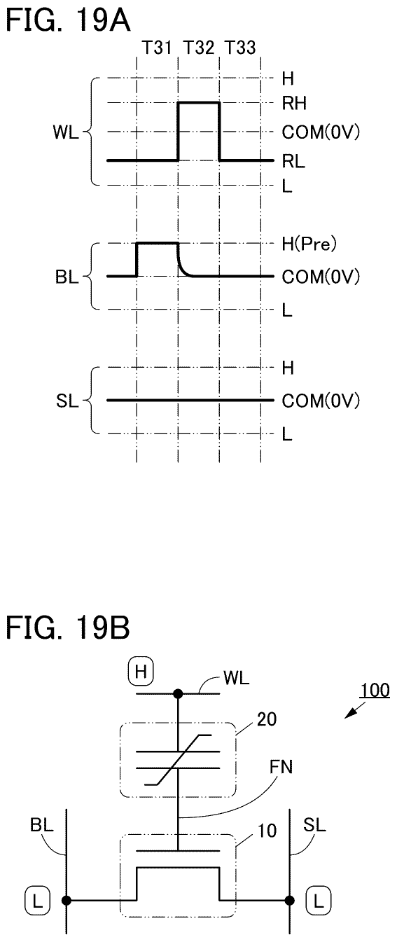

Next, operation of reading data retained in the semiconductor device 100A functioning as a memory cell will be described. FIG. 19A is a timing chart for describing the reading operation. FIG. 19B is a circuit diagram illustrating a state of the semiconductor device 100 in Period T31.

In this embodiment, the reading operation of the semiconductor device 100A that retains data “1” is described.

In Period T31, the wiring BL is precharged with the potential H. That is, after the potential of the wiring BL is set to the potential H, the wiring BL is brought into a floating state (a state where electric power is supplied from nowhere). In addition, the potential COM is supplied to the wiring SL.

Next, in Period T32, a potential RH that is a reading potential is supplied to the wiring WL. The potential RH is a potential higher than or equal to the threshold voltage of the characteristics 291 and lower than the threshold voltage of the characteristics 292. Moreover, in order to hardly cause a change in polarization of the insulating layer 167, the potential RH is set to a voltage with which the voltage applied to the capacitor element 20 is lower than or equal to the coercive voltage +Vc.

In the case where the data “1” is retained in the semiconductor device 100A, when the potential RH is supplied to the wiring WL, the transistor 10 is turned on, and a current Id1 flows between the source and the drain (see FIG. 16C). Thus, electrical continuity is established between the wiring BL and the wiring SL, and the potential of the wiring BL that is in a floating state changes toward the potential COM.

The case where the potential of the wiring BL changes after the potential RH is supplied to the wiring WL can be determined that the data “1” has been written to the semiconductor device 100A. The case where it is judged that the potential of the wiring BL does not change even when the potential RH is supplied to the wiring WL can be determined that the data “0” has been written to the semiconductor device 100A.

After the reading operation, the potential RL is supplied to the wiring WL in Period T33. Since the potential RH is set to a voltage with which the voltage applied to the capacitor element 20 is lower than or equal to the coercive voltage +Vc, the polarization of the insulating layer 167 included in the capacitor element 20 is less likely to change. Thus, non-destructive reading of the semiconductor device 100A can be achieved.

Note that the hysteresis characteristics of the ferroelectric change depending on the material, the structure, and the formation method. Accordingly, the potential RH is preferably a voltage with which the voltage applied to the capacitor element 20 is less than or equal to 0.8 times, preferably less than or equal to 0.6 times the coercive voltage +Vc. Moreover, the potential RL is preferably a voltage with which the voltage applied to the capacitor element 20 is greater than or equal to 0.8 times, preferably greater than or equal to 0.6 times the coercive voltage −Vc.

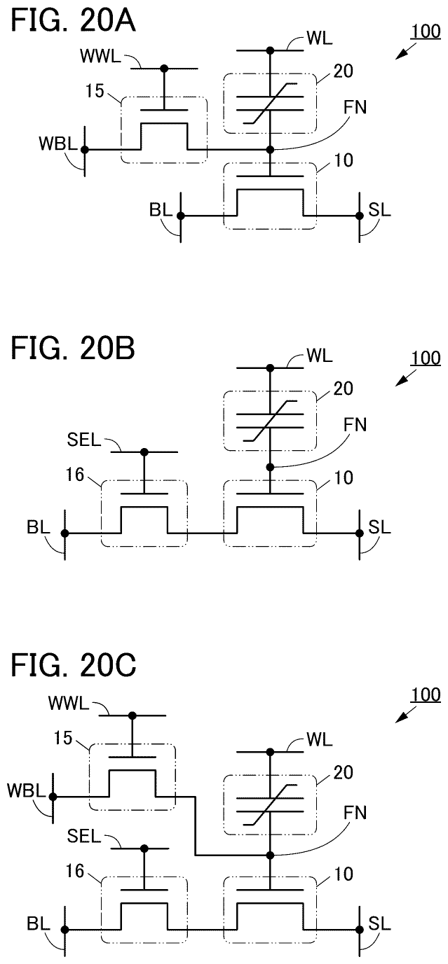

The structure of the semiconductor device 100 functioning as a memory cell is not limited to the above structure. For example, as illustrated in the equivalent circuit diagram in FIG. 20A, a transistor 15 may be connected to the node FN. The semiconductor device 100 illustrated in the equivalent circuit diagram in FIG. 20A is a “2Tr1FE” memory cell including two transistors and one ferroelectric capacitor.

In the semiconductor device 100 illustrated in the equivalent circuit diagram in FIG. 20A, a gate of the transistor 15 is electrically connected to a wiring WWL, one of a source and a drain of the transistor 15 is electrically connected to a wiring WBL, and the other of the source and the drain of the transistor 15 is electrically connected to the node FN. In the circuit structure illustrated in FIG. 20A, a potential can be supplied from the wiring WBL to the node FN through the transistor 15; thus, the operation voltage of the semiconductor device 100 required for data writing can be reduced.

The semiconductor device 100 illustrated in the equivalent circuit diagram in FIG. 20B is also a “2Tr1FE” memory cell. In the semiconductor device 100 illustrated in FIG. 20B, a gate of a transistor 16 is electrically connected to a wiring SEL, one of a source and a drain of the transistor 16 is electrically connected to the wiring BL, and the other of the source and the drain of the transistor 16 is electrically connected to one of the source and the drain of the transistor 10. In the circuit structure illustrated in FIG. 20A, the voltage applied to the capacitor element 20 at the time of data reading can be reduced, so that the data retention period of the semiconductor device 100 can be extended. In addition, the reliability of the semiconductor device 100 can be increased.

As in the semiconductor device 100 illustrated in the equivalent circuit diagram in FIG. 20C, the structure illustrated in FIG. 20A may be combined with the structure illustrated in FIG. 20B. The semiconductor device 100 illustrated in the equivalent circuit diagram in FIG. 20C is a “3Tr1FE” memory cell.

This embodiment can be combined as appropriate with any of the other embodiments and the like described in this specification.

### Embodiment 2

In this embodiment, an oxide semiconductor that can be used in the OS transistor described in the above embodiment will be described.

Any of the metal oxides described in the above embodiment can be used as a metal oxide of the OS transistor. Hereinafter, In—Ga—Zn oxide is described as an example of the metal oxide.

### <Classification of Crystal Structure>

Examples of crystal structures of an oxide semiconductor include amorphous (including completely amorphous), CAAC (c-axis-aligned crystalline), nc (nanocrystalline), CAC (cloud-aligned composite), single crystal, and polycrystalline (poly crystal) structures.

A crystal structure of a film or a substrate can be evaluated with an X-ray diffraction (XRD) spectrum. For example, evaluation is possible using an XRD spectrum obtained by GIXD (Grazing-Incidence XRD) measurement. Note that a GIXD method is also referred to as a thin film method or a Seemann-Bohlin method. The XRD spectrum obtained by GIXD measurement is hereinafter simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film formed at room temperature. Thus, it is suggested that the In—Ga—Zn oxide film formed at room temperature is in an intermediate state, which is neither a single crystal nor polycrystal nor an amorphous state, and it cannot be concluded that In—Ga—Zn oxide film is in an amorphous state.

### [Structure of Oxide Semiconductor]

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the CAAC-OS and the nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

In the case of In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga, Zn) layer) are stacked. Indium and gallium can be replaced with each other. Therefore, indium may be contained in the (Ga, Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear grain boundary is observed is what is called polycrystal. It is highly probable that the grain boundary becomes a recombination center and traps carriers and thus decreases the on-state current and field-effect mobility of a transistor, for example. Thus, the CAAC-OS in which no clear grain boundary is observed is one of crystalline oxides having a crystal structure suitable for a semiconductor layer of a transistor. Note that Zn is preferably contained to form the CAAC-OS. For example, In—Zn oxide and In—Ga—Zn oxide are suitable because they can inhibit generation of a grain boundary as compared with In oxide.

The CAAC-OS is an oxide semiconductor with high crystallinity in which no clear grain boundary is observed. Thus, in the CAAC-OS, a reduction in electron mobility due to the grain boundary is unlikely to occur. Moreover, since the crystallinity of an oxide semiconductor might be decreased by entry of impurities, formation of defects, and/or the like, the CAAC-OS can be regarded as an oxide semiconductor that has small amounts of impurities and defects (e.g., oxygen vacancies). Hence, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Hence, the orientation in the whole film is not observed. Accordingly, in some cases, the nc-OS cannot be distinguished from an a-like OS and an amorphous oxide semiconductor, depending on the analysis method. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-like OS]

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### [Structure of Oxide Semiconductor]

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region containing indium oxide, indium zinc oxide, or the like as its main component. The second region is a region containing gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In a material composition of a CAC-OS in In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated intentionally, for example. In the case where the CAC-OS is formed by a sputtering method, any one or more selected from an inert gas (typically, argon), an oxygen gas, and a nitrogen gas is used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region is a region having higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices such as display devices.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Impurity>

Here, the influence of each impurity in the oxide semiconductor will be described.

When silicon or carbon, which is one of Group 14 elements, is contained in the oxide semiconductor, defect states are formed in the oxide semiconductor. Therefore, in the case where the oxide semiconductor is used for a semiconductor layer of a normally-off transistor, the concentration of silicon or carbon in the oxide semiconductor (the concentration obtained by secondary ion mass spectrometry (SIMS)) is lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Therefore, a normally-on transistor is easily obtained with the use of the oxide semiconductor containing an alkali metal or an alkaline earth metal. Meanwhile, when the oxide semiconductor is used for a semiconductor layer of a normally-off transistor, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. As a result, when an oxide semiconductor containing nitrogen is used for a semiconductor, a normally-on transistor is easily obtained. Meanwhile, when the oxide semiconductor is used for a semiconductor layer of a normally-off transistor, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Accordingly, when an oxide semiconductor containing hydrogen is used, a normally-on transistor is easily obtained. Meanwhile, when the oxide semiconductor is used for a semiconductor layer of a normally-off transistor, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

This embodiment can be combined as appropriate with any of the other embodiments and the like described in this specification.

### Embodiment 3

In this embodiment, a structure example of a storage device 300 including the semiconductor device 100 (the semiconductor device 100A, the semiconductor device 100Aa, the semiconductor device 100B, the semiconductor device 100Ba, the semiconductor device 100C, the semiconductor device 100Ca, the semiconductor device 100D, the semiconductor device 100E, or the semiconductor device 100Ea) functioning as a memory cell will be described. The semiconductor device 200 may be used as the semiconductor device 100.

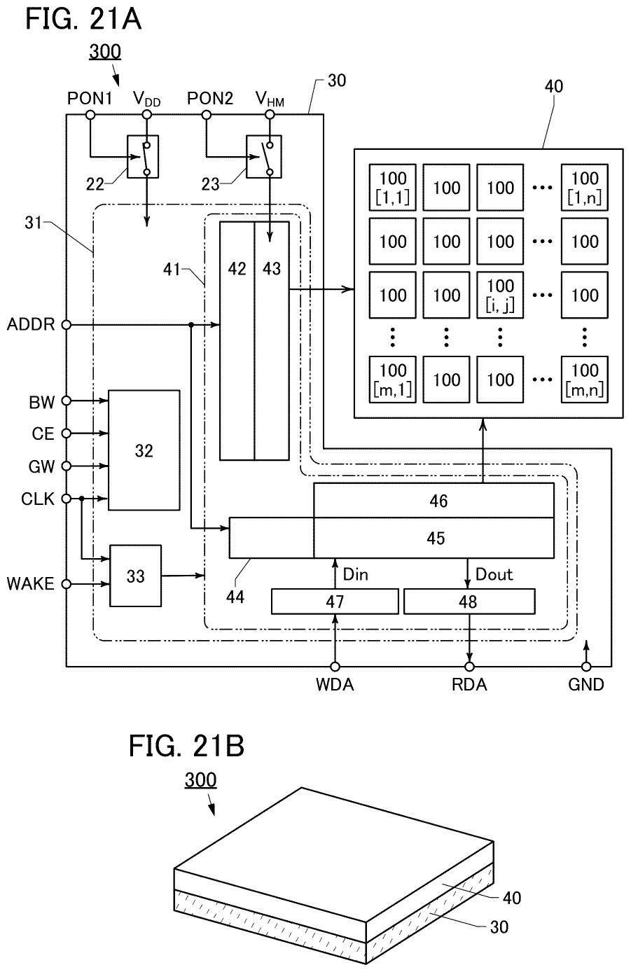

FIG. 21A is a block diagram illustrating a structure example of the storage device 300. The storage device 300 includes a driver circuit 30 and a memory array 40. The memory array 40 includes a plurality of semiconductor devices 100. FIG. 21A illustrates an example in which the memory array 40 includes the plurality of semiconductor devices 100 arranged in a matrix of m rows and n columns (m is an integer of greater than or equal to 2 and n is an integer of greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 21A, the semiconductor device 100 in the first row and the first column is denoted by a semiconductor device 100[1,1]; the semiconductor device 100 in the first row and the n-th column is denoted by a semiconductor device 100[1,n]; the semiconductor device 100 in the m-th row and the first column is denoted by a semiconductor device 100[m,1]; and the semiconductor device 100 in the m-th row and the n-th column is denoted by a semiconductor device 100[m,n]. Furthermore, the semiconductor device 100 in the i-th row and the j-th column (i is an integer greater than or equal to 1 and less than or equal to m and j is an integer greater than or equal to 1 and less than or equal to n) is denoted by a semiconductor device 100[i,j].

The memory array 40 includes m wirings WL extending in the row direction and n wirings SL and n wirings BL extending in the column direction (not illustrated). In this specification and the like, an i-th (i-th row) wiring WL is denoted by a wiring WL[i] in some cases. Aj-th (j-th column) wiring SL is denoted by a wiring SL[j] in some cases. Aj-th (j-th column) wiring BL is denoted by a wiring BL[j] in some cases.

The plurality of semiconductor devices 100 provided in the j-th column are electrically connected to the wiring BL[j] and the wiring SL[j] (not illustrated). The plurality of semiconductor devices 100 provided in the i-th row are electrically connected to the wiring WL[i] (not illustrated).

The driver circuit 30 includes a PSW 22 (power switch), a PSW 23, and a peripheral circuit 31. The peripheral circuit 31 includes a peripheral circuit 41, a control circuit 32, and a voltage generation circuit 33.

In the storage device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 300. For example, the control circuit performs a logical operation on the signal CE, the signal GW, and the signal BW to determine an operation mode (e.g., a writing operation or a reading operation) of the storage device 300. Alternatively, the control circuit 32 generates a control signal for the peripheral circuit 41 so that the operation mode is executed.

The voltage generation circuit 33 has a function of generating voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates voltage.

The peripheral circuit 41 is a circuit for writing and reading data to/from the semiconductor devices 100. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the semiconductor devices 100, a function of reading data from the semiconductor devices 100, a function of retaining the read data, and the like.

The input circuit 47 has a function of retaining the signal WDA. Data retained by the input circuit 47 is output to the column driver 45. Data output from the input circuit 47 is data (Din) to be written to the semiconductor devices 100. Data (Dout) read from the semiconductor devices 100 by the column driver 45 is output to the output circuit 48. The output circuit 48 has a function of retaining Dout. In addition, the output circuit 48 has a function of outputting Dout to the outside of the storage device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 300, a high power supply potential is VDD and a low power supply potential is GND (a ground potential). In addition, VHM is a high power supply potential used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 21A but can be more than one. In that case, a power switch is provided for each power domain.

The driver circuit 30 and the memory array 40 may be provided on the same plane. As illustrated in FIG. 21B, the driver circuit 30 and the memory array 40 may be provided to overlap with each other. When the driver circuit 30 and the memory array 40 are provided to overlap with each other, the signal transmission distance can be shortened. Accordingly, resistance and parasitic capacitance between the driver circuit 30 and the memory array 40 are reduced, so that power consumption and signal delays can be reduced. In addition, the storage device 300 can be downsized. A plurality of memory arrays 40 may overlap with each other over the driver circuit 30.

As described above, according to one embodiment of the present invention, the semiconductor device 100 that occupies a small area can be achieved. The semiconductor device 100 functions as a memory cell. When the semiconductor device 100 is used as a memory cell of the storage device 300, the number of memory cells per unit area (also referred to as “storage density”) can be increased. Thus, the storage device 300 with high storage capacity can be achieved.

This embodiment can be combined as appropriate with any of the other embodiments and the like described in this specification.

### Embodiment 4

In this embodiment, examples of electronic components in which the semiconductor device or the like described in any of the above embodiments is incorporated will be described.

### <Electronic Component>

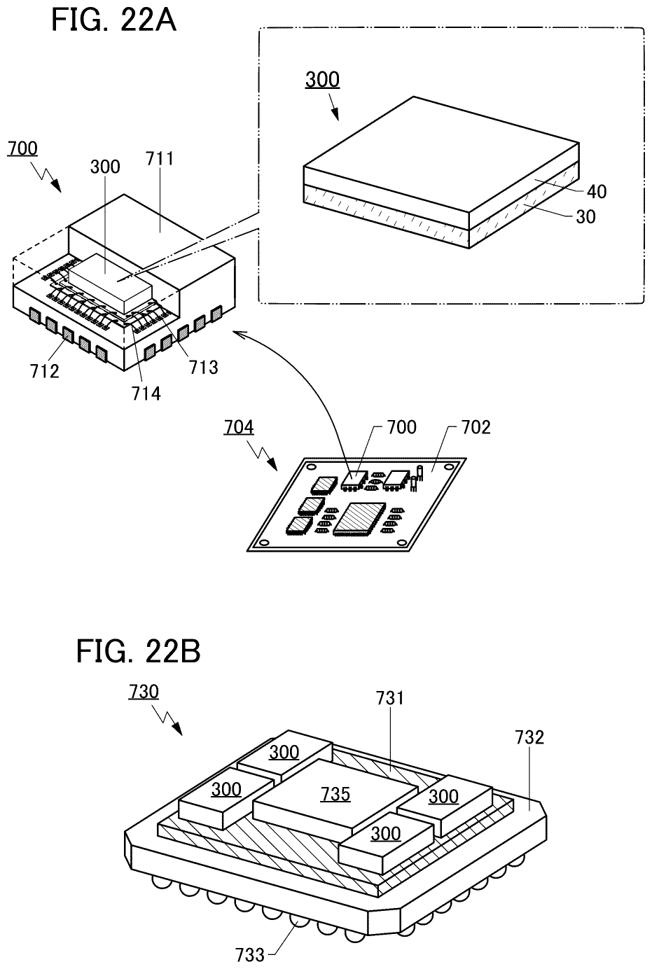

FIG. 22A is a perspective view of an electronic component 700 and a substrate (a circuit board 704) on which the electronic component 700 is mounted. The electronic component 700 illustrated in FIG. 22A includes the storage device 300, which is a kind of semiconductor devices, in a mold 711. FIG. 22A omits some parts to show the inside of the electronic component 700. The electronic component 700 includes a land 712 outside the mold 711. The land 712 is electrically connected to an electrode pad 713, and the electrode pad 713 is electrically connected to the storage device 300 via a wire 714. The electronic component 700 is mounted on a printed circuit board 702, for example. A plurality of such electronic components are combined and electrically connected to each other on the printed circuit board 702, which forms the circuit board 704.

The storage device 300 includes the driver circuit 30 and the memory array 40. Alternatively, a plurality of layers of memory arrays 40 may be provided over the driver circuit 30.

FIG. 22B is a perspective view of an electronic component 730. The electronic component 730 is an example of a SiP (System in Package) or an MCM (Multi Chip Module). In the electronic component 730, an interposer 731 is provided over a package substrate 732 (printed circuit board) and a semiconductor device 735 and a plurality of storage devices 300 are provided over the interposer 731.

The electronic component 730 using the storage device 300 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer, which does not need to be provided with an active element, can be manufactured at lower cost than an integrated circuit. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 300 and the semiconductor device 735 are preferably the same, for example.

An electrode 733 may be provided on the bottom portion of the package substrate 732 to mount the electronic component 730 on another substrate. FIG. 22B illustrates an example where the electrode 733 is formed of a solder ball. Solder balls are provided in a matrix on the bottom portion of the package substrate 732, whereby a BGA (Ball Grid Array) can be achieved. Alternatively, the electrode 733 may be formed of a conductive pin. When conductive pins are provided in a matrix on the bottom portion of the package substrate 732, a PGA (Pin Grid Array) can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

This embodiment can be combined as appropriate with any of the other embodiments and the like described in this specification.

### Embodiment 5

In this embodiment, application examples of the storage device of one embodiment of the present invention will be described.

The storage device of one embodiment of the present invention can be applied to, for example, storage devices of a variety of electronic devices (e.g., information terminals, computers, smartphones, e-book readers, digital still cameras, video cameras, video recording/reproducing devices, navigation systems, game machines, and the like). In addition, the storage device can also be used for image sensors, IoT (Internet of Things), healthcare-related devices, and the like. Note that here, the computers refer not only to tablet computers, laptop computers, and desktop computers, but also to large computers such as server systems.

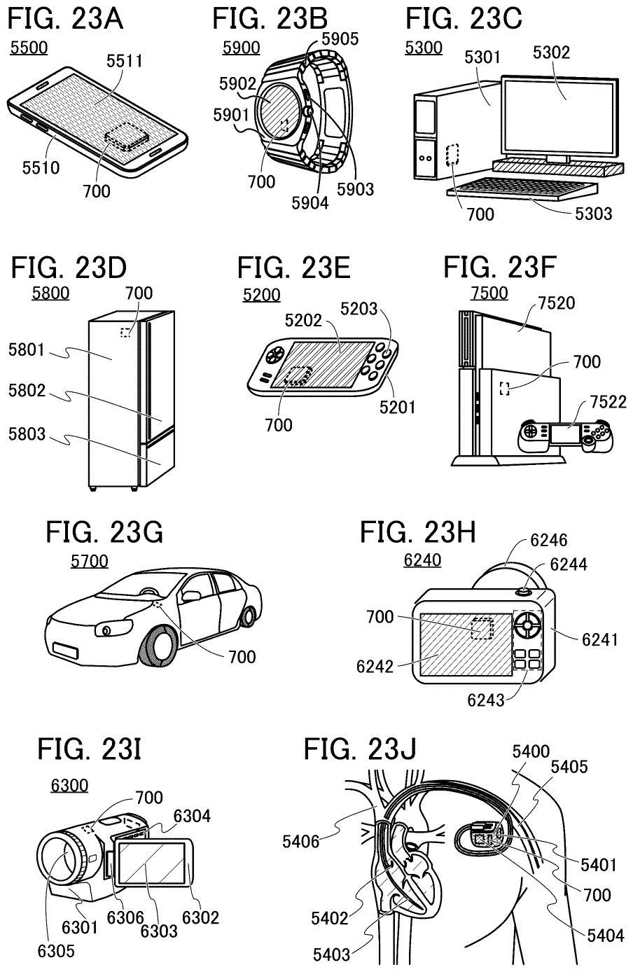

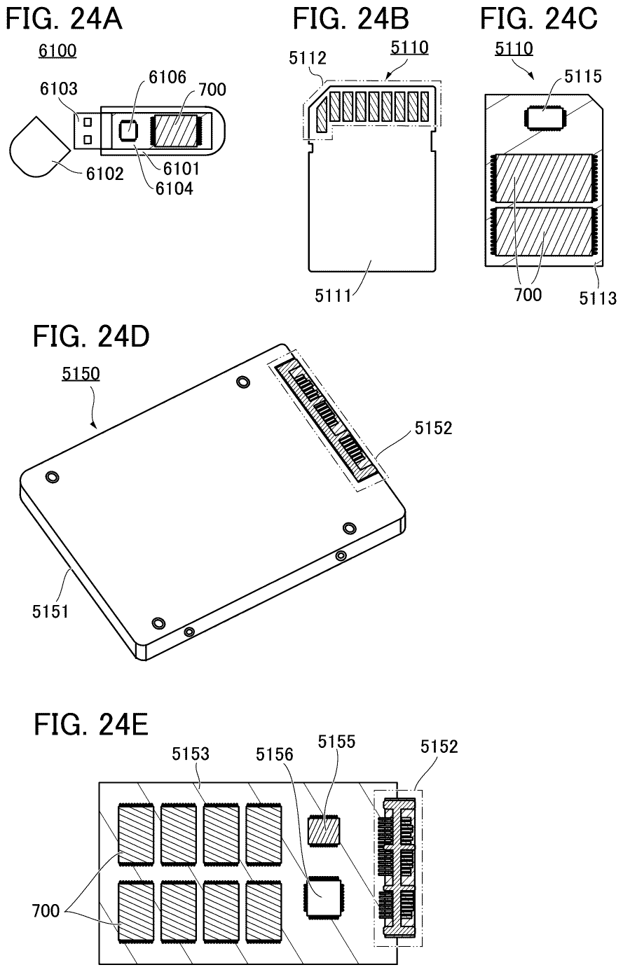

Examples of an electronic device including the storage device of one embodiment of the present invention will be described. Note that FIG. 23A to FIG. 23J and FIG. 24A to FIG. 24E each illustrate a state where the electronic component 700 or the electronic component 730, each of which includes the storage device, is included in an electronic device.

### [Cellular Phone]

An information terminal 5500 illustrated in FIG. 23A is a cellular phone (smartphone), which is a type of information terminal. The information terminal 5500 includes a housing 5510 and a display portion 5511, and as input interfaces, a touch panel is provided in the display portion 5511 and a button is provided in the housing 5510.

By applying the storage device of one embodiment of the present invention to the information terminal 5500, the information terminal 5500 can retain a temporary file generated at the time of executing an application (e.g., a web browser's cache or the like).

### [Wearable Terminal]

FIG. 23B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by applying the storage device of one embodiment of the present invention to the wearable terminal.

### [Information Terminal]

FIG. 23C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by applying the storage device of one embodiment of the present invention to the desktop information terminal 5300.

Note that although the smartphone, the wearable terminal, and the desktop information terminal are respectively illustrated in FIG. 23A to FIG. 23C as examples of the electronic device, one embodiment of the present invention can be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

FIG. 23D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT.

The storage device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal and the like via the Internet. In the electric refrigerator-freezer 5800, the semiconductor device can retain a temporary file generated at the time of transmitting the information.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 23E illustrates a portable game machine 5200 as an example of a game machine. The portable game machine 5200 includes a housing 5201, a display portion 5202, a button 5203, and the like.

FIG. 23F illustrates a stationary game machine 7500 as another example of a game machine. The stationary game machine 7500 includes a main body 7520 and a controller 7522. Note that the controller 7522 can be connected to the main body 7520 with or without a wire. Although not illustrated in FIG. 23F, the controller 7522 can include a display portion that displays a game image, and an input interface besides a button, such as a touch panel, a stick, a rotating knob, and a sliding knob, for example. The shape of the controller 7522 is not limited to that illustrated in FIG. 23F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

Videos displayed on the game machine can be output with a display device such as a television device, a personal computer display, a game display, or a head-mounted display.

The storage device described in any of the above embodiments is applied to the portable game machine 5200 or the stationary game machine 7500, so that the portable game machine 5200 with low power consumption or the stationary game machine 7500 with low power consumption can be achieved. Moreover, heat generation from a circuit can be reduced owing to low power consumption; thus, the influence of heat generation on the circuit itself, a peripheral circuit, and a module can be reduced.

When the storage device described in any of the above embodiments is applied to the portable game machine 5200 or the stationary game machine 7500, it is possible to retain a temporary file necessary for arithmetic operation that occurs during game play.

As an example of a game machine, FIG. 23E illustrates a portable game machine. FIG. 23F illustrates a home-use stationary game machine. Note that an electronic device of one embodiment of the present invention is not limited thereto. Examples of the electronic device of one embodiment of the present invention include an arcade game machine installed in entertainment facilities (a game center, an amusement park, and the like), and a throwing machine for batting practice installed in sports facilities.

### [Moving Vehicle]

The storage device described in any of the above embodiments can be applied to a motor vehicle, which is a moving vehicle, and around the driver's seat in a motor vehicle.

FIG. 23G illustrates a motor vehicle 5700 as an example of a moving vehicle.

An instrument panel that provides various kinds of information such as a speedometer, a tachometer, a mileage, a fuel meter, a gearshift state, and air-conditioning settings is provided around the driver's seat in the motor vehicle 5700. A storage device showing the above information may be provided around the driver's seat.

In particular, the display device can compensate for the view obstructed by a pillar or the like, blind areas for the driver's seat, and the like by displaying a video from an imaging device (not illustrated) provided for the motor vehicle 5700, which can increase safety. That is, display of an image from an imaging device provided on the outside of the motor vehicle 5700 can fill in blind areas and increase safety.

The semiconductor device described in any of the above embodiments can temporarily hold information; thus, the storage device can be used to hold temporary information necessary in a system conducting automatic driving, navigation, and risk prediction for the motor vehicle 5700, for example. The display device may be configured to display temporary information regarding navigation, risk prediction, or the like. Moreover, the semiconductor device may be configured to hold a video of a driving recorder provided in the motor vehicle 5700.

Although a motor vehicle is described above as an example of a moving vehicle, the moving vehicle is not limited to a motor vehicle. Examples of moving vehicles include a train, a monorail train, a ship, a flying object (a helicopter, an unmanned aircraft (a drone), and an airplane, and a rocket).

### [Camera]

The storage device described in any of the above embodiments can be applied to a camera.

FIG. 23H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that here, the digital camera 6240 is configured such that the lens 6246 is detachable from the housing 6241 for replacement; alternatively, the lens 6246 may be integrated with the housing 6241. In addition, the digital camera 6240 can be additionally equipped with a stroboscope, a viewfinder, or the like.

When the storage device described in any of the above embodiments is applied to the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The storage device described in any of the above embodiments can be applied to a video camera.

FIG. 23I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and the angle between the first housing 6301 and the second housing 6302 can be changed with the joint 6306. Videos displayed on the display portion 6303 may be changed in accordance with the angle at the joint 6306 between the first housing 6301 and the second housing 6302.

When videos taken by the video camera 6300 are recorded, the videos need to be encoded in accordance with a data recording format. With the use of the above semiconductor device, the video camera 6300 can retain a temporary file generated in encoding.

### [ICD]

The storage device described in any of the above embodiments can be applied to an implantable cardioverter-defibrillator (ICD).

FIG. 23J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In the case where the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor or the like, the number of times the treatment with pacing is performed, and the time taken for the treatment, for example, can be stored in the electronic component 700.

The antenna 5404 can receive electric power, and the battery 5401 is charged with the electric power. When the ICD main unit 5400 includes a plurality of batteries, safety can be increased. Specifically, even when some of the batteries in the ICD main unit 5400 are dead, the other batteries can function properly; thus, the batteries also function as an auxiliary power source.

In addition to the antenna 5404 capable of receiving electric power, an antenna that can transmit physiological signals may be included to construct, for example, a system that monitors cardiac activity by checking physiological signals such as a pulse, a respiratory rate, a heart rate, and body temperature with an external monitoring device.

### [Expansion Device for PC]

The semiconductor device described in any of the above embodiments can be applied to a calculator such as a PC (Personal Computer) and an expansion device for an information terminal.

FIG. 24A illustrates, as an example of the expansion device, a portable expansion device 6100 that includes a chip capable of holding information and is externally provided on a PC. The expansion device 6100 can store information using the chip when connected to a PC with a USB (Universal Serial Bus) or the like, for example. Note that FIG. 24A illustrates the portable expansion device 6100; however, the expansion device of one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device or the like described in any of the above embodiments. For example, the substrate 6104 is provided with the electronic component 700 and a controller chip 6106. The USB connector 6103 functions as an interface for connection to an external device.

### [SD Card]

The storage device described in any of the above embodiments can be applied to an SD card that can be attached to an electronic device such as an information terminal or a digital camera.

FIG. 24B is a schematic external view of an SD card, and FIG. 24C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a storage device and a circuit for driving the storage device. For example, the electronic components 700 and a controller chip 5115 are attached to the substrate 5113. Note that the circuit structures of the electronic components 700 and the controller chip 5115 are not limited to those described above, and can be changed as appropriate according to circumstances. For example, a write circuit, a row driver, a read circuit, and the like that are provided in an electronic component may be incorporated into the controller chip 5115 instead of the electronic component 700.

When the electronic components 700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 700.

### [SSD]

The storage device described in any of the above embodiments can be applied to an SSD (Solid State Drive) that can be attached to an electronic device such as an information terminal.

FIG. 24D is a schematic external view of an SSD, and FIG. 24E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a storage device and a circuit for driving the storage device. For example, the electronic components 700, a memory chip 5155, and a controller chip 5156 are attached to the substrate 5153. When the electronic components 700 are also provided on a rear surface side of the substrate 5153, the capacity of the SSD 5150 can be increased. A work memory is incorporated in the memory chip 5155. For example, a DRAM chip is used as the memory chip 5155. A processor, an ECC circuit, and the like are incorporated in the controller chip 5156. Note that the circuit structures of the electronic components 700, the memory chip 5155, and the controller chip 5115 are not limited to those described above, and the circuit structures can be changed as appropriate according to circumstances. For example, a memory functioning as a work memory may also be provided in the controller chip 5156.

### [Computer]

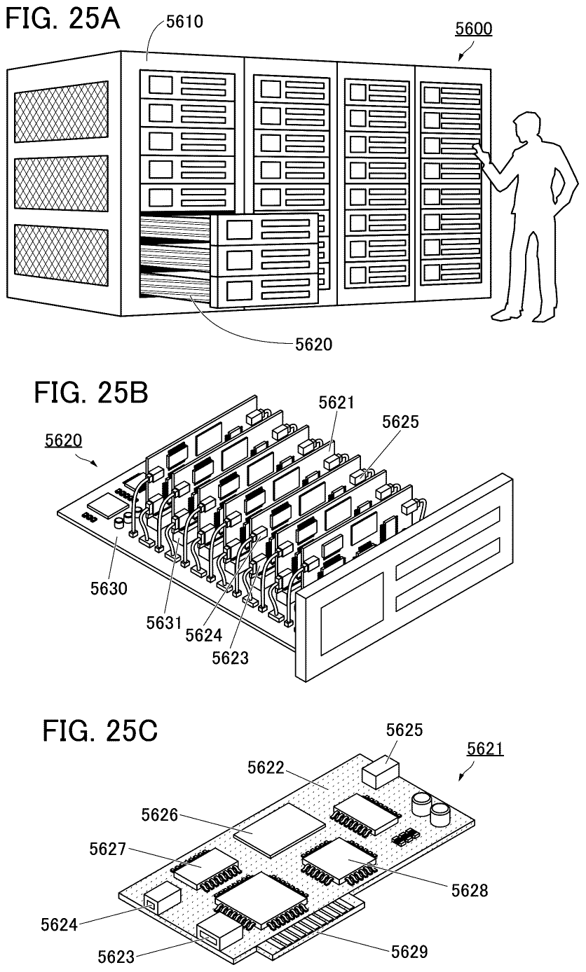

A computer 5600 illustrated in FIG. 25A is an example of a large computer. In the computer 5600, a plurality of rack mount computers 5620 are stored in a rack 5610.

The computer 5620 can have a structure in a perspective view illustrated in FIG. 25B, for example. In FIG. 25B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 25C is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 25C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

When the storage device of one embodiment of the present invention is used in a variety of electronic devices or the like described above, reduction in size and power consumption of the electronic device can be achieved. In addition, since the storage device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the storage device of one embodiment of the present invention can achieve an electronic device that operates stably even in a high temperature environment. Thus, the reliability of the electronic devices can be increased.

This embodiment can be combined as appropriate with any of the other embodiments and the like described in this specification.

### Embodiment 6

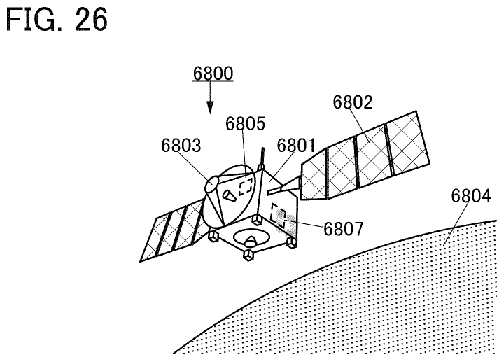

The semiconductor device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, OS transistors can be suitably used in outer space. In this embodiment, a specific example of using the semiconductor device of one embodiment of the present invention in a device for space will be described with reference to FIG. 26.

FIG. 26 illustrates an artificial satellite 6800 as an example of a device for space. The artificial satellite 6800 includes a body 6801, a solar panel 6802, an antenna 6803, a secondary battery 6805, and a control device 6807. In FIG. 26, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, electric power required for operation of the artificial satellite 6800 might not be generated. In order to operate the artificial satellite 6800 even with a small amount of generated electric power, the artificial satellite 6800 is provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

This embodiment can be combined as appropriate with any of the other embodiments and the like described in this specification.

### REFERENCE NUMERALS

10: transistor, 20: capacitor element, 100: semiconductor device, 141: insulating layer, 142: conductive layer, 143: conductive layer, 144: opening, 145: insulating layer, 146: conductive layer, 147: insulating layer, 148: insulating layer, 154: insulating layer, 155: conductive layer, 156: insulating layer, 157: insulating layer, 158: insulating layer, 159: opening, 160: conductive layer, 161: semiconductor layer, 162: insulating layer, 163: conductive layer, 164: insulating layer, 167: insulating layer, 168: conductive layer, 180: portion

1. A semiconductor device comprising:
a transistor and a capacitor element;
a first conductive layer comprising a region configured to be one of a source electrode and a drain electrode of the transistor;
a first insulating layer comprising a region positioned over the first conductive layer;
a second conductive layer comprising a region configured to be the other of the source electrode and the drain electrode of the transistor and comprising a region positioned over the first insulating layer;
an opening passing through the first insulating layer and the second conductive layer and overlapping with the first conductive layer;
a semiconductor layer comprising a region in contact with the first insulating layer, a region in contact with the first conductive layer, and a region in contact with the second conductive layer;
a third conductive layer comprising a region configured to be a gate electrode of the transistor;
a second insulating layer comprising a region configured to be a gate insulating layer of the transistor and comprising a region interposed between the semiconductor layer and the third conductive layer in the opening;
a fourth conductive layer comprising a region configured to be one electrode of the capacitor element; and
a third insulating layer comprising a region configured to be a dielectric layer of the capacitor element and comprising a region interposed between the third conductive layer and the fourth conductive layer in the opening,
wherein the third conductive layer comprises a region configured to be the other electrode of the capacitor element, and
wherein the third insulating layer has ferroelectricity.

2. The semiconductor device according to claim 1,
wherein the semiconductor layer comprises an oxide semiconductor.

3. The semiconductor device according to claim 2,
wherein the oxide semiconductor comprises at least one of indium and zinc.

4. The semiconductor device according to claim 1,
wherein the third insulating layer comprises at least one of hafnium and zirconium.

5. The semiconductor device according to claim 1,
wherein the first insulating layer comprises:
a layer comprising silicon and nitrogen; and
a layer comprising silicon and oxygen.
